(19) United States
(12) Patent Application Publication
(10) Pub. No.: US 2011/0298070 A1
(43) Pub. Date: Dec. 8, 2011

(54) Semiconductor Device Having Magnetoresistive Element and Manufacturing Method Thereof

(75) Inventors: Shoichi Fukui, Kanagawa (JP); Satoshi Iida, Kanagawa (JP); Shinroku Maejima, Kanagawa (JP); Kazuyuki Omori, Kanagawa (JP)

(73) Assignee: Renesas Electronics Corporation, Kawasaki-shi (JP)

(21) Appl. No.: 13/150,968

(22) Filed: Jun. 1, 2011

(30) Foreign Application Priority Data
Jun. 3, 2010 (JP) 2010-127766

(51) Int. Cl. H01L 29/82; H01L 21/8246

(52) U.S. Cl. 257/422; 438/3; 257/E29.323; 257/E21.665

(57) ABSTRACT

A semiconductor device has a magnetoresistive element, a bit line over the magnetoresistive element, and a yoke cover over the bit line. To form the yoke cover, a laminate film is first formed over the bit line, the laminate film having a first barrier metal layer, a magnetic layer, and a second barrier metal layer which are formed successively over the bit line. Then, the laminate film is subjected to: reactive ion etching with a gas mixture of a carbon tetrafluoride (CF₄) gas and an argon (Ar) gas, reactive ion etching with a gas mixture of carbon monoxide (CO), an ammonia (NH₃) gas, and an argon (Ar) gas, and reactive ion etching with a gas mixture of a carbon tetrafluoride (CF₄) gas and an argon (Ar) gas.

### CROSS-REFERENCE TO RELATED APPLICATIONS

The disclosure of Japanese Patent Application No. 2010-127766 filed on Jun. 3, 2010 including the specification, drawings and abstract is incorporated herein by reference in its entirety.

### BACKGROUND

The present invention concerns a semiconductor device and a manufacturing method thereof and it particularly relates to a semiconductor device having a magnetoresistive element and a manufacturing method thereof.

Semiconductor devices include a magnetic random access memory (MRAM) using a magntoresistive element referred to as MTJ (Magnetic Tunnel Junction). In a MRAM, magnetoresistive elements are formed as an array where they are arranged at intersections between digit lines extending in one direction and bit lines extending in a direction substantially perpendicular therewith. In each of the magnetoresistive elements, two magnetic layers are laminated with a tunnel insulating film interposed therebetween.

For decreasing power consumption and efficiently concentrating a magnetic field to the magnetoresistive element in the MRAM, an interconnect structure including a clad layer is adapted as a structure for digit lines and bit lines in recent years. The clad layer has a function of shielding a magnetic field. For this purpose, in a digit line arranged below the magnetoresistive element, the clad layer is formed so as to cover the lateral side and the lower surface of the digit line except for the upper surface of the digit line at a portion arranged just below the magnetoresistive element. On the other hand, in a bit line arranged above the magnetoresistive element, the clad layer is formed so as to cover the lateral side and the upper surface of the bit line except for the lower surface of the bit line at a portion arranged just above the magnetoresistive element.

As a method of forming a clad layer covering the upper surface of the bit line, JP-T-2006-511956, for example, proposes a method of forming the clad layer to an inter-layer insulating film covering the bit line by a damascene method. That is, a layer is formed at first as a clad layer so as to cover the bottom and lateral sides of a trench formed in the inter-layer insulating film along the bit line. Then, other inter-layer insulating film is formed above the layer as the clad layer so as to fill the trench. Then, among the layers as the clad layer, a portion arranged above the upper surface of other inter-layer insulating film and a portion arranged on the lateral side of the trench are removed by applying chemical mechanical polishing to other inter-layer insulating film and the inter-layer insulating film. Thus, the portion of the clad layer arranged over the bottom of the groove which is left not polished is formed as a lid-like clad layer that covers the upper surface of the bit line.

### SUMMARY

However, existent semiconductor devices include the following problems. As described above, since the clad layer covering the upper surface of the bit line is formed by the damascene method, improvement of the throughput is difficult and the production cost cannot be lowered effectively. Further, as another problem, an amount of polishing varies within the plane of a wafer and the variation of the amount of polishing gives an undesired effect on the characteristic and the yield of semiconductor devices.

A method of manufacturing a semiconductor device according to an embodiment of the invention includes the following steps. A magnetoresistive element is formed over a main surface of a semiconductor substrate. A bit line extending in a predetermined direction is formed just above the magnetoresistive element at a distance. A predetermined laminate film is formed so as to cover the bit line. A yoke cover for shielding a magnetic field generated by a current flowing in the bit line is formed by fabricating the laminate film. The step of forming the laminate film includes the following steps. A first adhesion layer is formed so as to cover the bit line, a magnetic layer for shielding a magnetic field is formed in contact with the surface of the first adhesion layer. A second adhesion layer is formed in contact with a surface of the magnetic layer. The step of forming a yoke cover includes the following steps. A resist mask is formed so as to cover the region arranged just above the bit line. The second adhesion layer is patterned by applying reactive ion etching with a halogen-based gas using the resist mask as an etching mask (first step). Reactive ion etching with ammonia and an argon-based gas is applied by using the patterned second adhesion layer as an etching mask (second step). Reactive ion etching with a gas containing carbon as an element is applied by using the patterned second adhesion layer as an etching mask (third step).

Another method of manufacturing a semiconductor device according to an embodiment of the invention includes the following steps. A magnetoresistive element is formed over the main surface of a semiconductor substrate. A bit line extending in a predetermined direction is formed just above the magnetoresistive element at a distance. An antidiffusion film for preventing an interconnect material of the bit line from diffusion is formed in contact with the upper surface of the bit line. A predetermined laminate film is formed in contact with the surface of the antidiffusion film. A yoke cover for shielding a magnetic field generated by a current flowing in the bit line is formed by fabricating the laminate film. A metal material is introduced into the antidiffusion film between the step of forming the antidiffusion film and the step of forming the laminate film, thereby forming a mixing layer containing the metal material from the surface for a predetermined depth of the antidiffusion film. The step of forming the laminate film includes the following steps. A magnetic layer for shielding a magnetic field is formed in contact with the surface of the antidiffusion film. An adhesion layer is formed in contact with the surface of the magnetic layer. A step of forming the yoke cover includes the following steps. A resist mask is formed so as to cover a region at the surface of the adhesion layer arranged just above the bit line. The adhesion layer is patterned by applying reactive ion etching with a halogen-based gas using the resist mask as an etching mask (first step), reactive ion etching with ammonia and an argon-based gas is applied to the patterned adhesion layer as an etching mask (second step), and reactive ion etching with a gas-containing carbon as an element by using the patterned adhesion layer as an etching mask (third step).

A semiconductor device according to an embodiment of the invention includes a magnetoresistive element, a bit line, and a yoke cover. The magnetoresistive element is formed over a main surface of the semiconductor substrate, and a bit line is formed just above the magnetoresistive element at a distance so as to extend in a predetermined direction. The yoke cover is formed so as to cover the upper surface of the bit line and shield a magnetic field generated by a current flowing in the bit line. The yoke cover has a predetermined laminate film in which the laminate facet is in a forward tapered shape. The predetermined laminate film includes a magnetic layer and an upper adhesion layer formed in contact with the upper surface of the magnetic layer. In the manufacturing method of the semiconductor device according to the invention, the production cost can be reduced while improving the throughput by forming the yoke cover covering the bit line by applying reactive ion etching to the predetermined laminate film.

In the semiconductor device of one embodiment of the invention, the laminate facet of the yoke cover is in a forward tapered shape by forming the yoke cover covering the bit line by applying reactive ion etching to the predetermined laminate film. This can increase the overlap margin between the bit line and the yoke cover without lowering the exposure margin when the resist mask for patterning the yoke cover is formed to suppress the leakage of a magnetic field and confine the magnetic field.

### BRIEF DESCRIPTION OF THE DRAWINGS

FIG. 1 is a perspective view schematically showing an arrangement of magnetoresistive elements, digit lines, and bit lines in a memory cell of a semiconductor device according to each of embodiments of the invention;

FIG. 2 is a plan view showing the layout of the memory cell in each of the embodiments;

FIG. 3 is a cross sectional view showing a memory cell in a semiconductor device according to a first embodiment of the invention, which includes a cross sectional view along a line IIIa-IIIa and a cross sectional view along a line IIIb-IIIb shown in FIG. 2;

FIG. 4 is a cross sectional view showing a peripheral circuit in the semiconductor device in the embodiment;

FIG. 5 is a fragmentary enlarged cross sectional view showing a bit line and a peripheral structure thereof in the embodiment;

FIG. 6 is a cross sectional view showing a step of a manufacturing method of a semiconductor device in the embodiment;

FIG. 7 is a cross sectional view showing a step which is performed succeeding to the step shown in FIG. 6 in the embodiment;

FIG. 8 is a cross sectional view showing a step which is performed succeeding to the step shown in FIG. 7 in the embodiment;

FIG. 9 is a cross sectional view showing a step which is performed succeeding to the step shown in FIG. 8 in the embodiment;

FIG. 10 is a cross sectional view showing a step which is performed succeeding to the step shown in FIG. 9 in the embodiment;

FIG. 11 is a cross sectional view showing a step which is performed succeeding to the step shown in FIG. 10 in the embodiment;

FIG. 12 is a cross sectional view showing a step which is performed succeeding to the step shown in FIG. 11 in the embodiment;

FIG. 13 is a cross sectional view showing a step which is performed succeeding to the step shown in FIG. 12 in the embodiment;

FIG. 14 is a cross sectional view showing a step which is performed succeeding to the step shown in FIG. 13 in the embodiment;

FIG. 15 is a cross sectional view showing a step which is performed succeeding to the step shown in FIG. 14 in the embodiment;

FIG. 16 is a cross sectional view showing a step which is performed succeeding to the step shown in FIG. 15 in the embodiment;

FIG. 17 is a cross sectional view showing a step which is performed succeeding to the step shown in FIG. 16 in the embodiment;

FIG. 18 is a cross sectional view showing a step which is performed succeeding to the step shown in FIG. 17 in the embodiment;

FIG. 19 is a cross sectional view showing a step which is performed succeeding to the step shown in FIG. 18 in the embodiment;

FIG. 20 is a cross sectional view showing a step which is performed succeeding to the step shown in FIG. 19 in the embodiment;

FIG. 21 is a cross sectional view showing a step of a manufacturing method of a semiconductor device according to a comparative embodiment;

FIG. 22 is a cross sectional view showing a step which is performed succeeding to the step shown in FIG. 21;

FIG. 23 is a cross sectional view showing a step which is performed succeeding to the step shown in FIG. 22;

FIG. 24 is a cross sectional view showing a step which is performed succeeding to the step shown in FIG. 23;

FIG. 25 is a fragmentary enlarged cross sectional view for explaining a thickness, etc. of a yoke cover in the embodiment;

FIG. 26 is a fragmentary enlarged plan view showing an alignment step for explaining the thickness of the yoke cover in the embodiment;

FIG. 27 is a cross sectional view along line XXVII-XXVII shown in FIG. 26 for explaining the thickness of the yoke cover;

FIG. 28 is a graph showing a relation between the displacement of alignment and the thickness of the laminate film in the embodiment;

FIG. 29 is a graph showing a relation between a magnetic flux density and a distance between a yoke cover and the upper surface of an interconnect;

FIG. 30 is a fragmentary enlarged cross sectional view showing a bit line and a peripheral structure thereof in a semiconductor device according to a comparative embodiment;

FIG. 31 is a fragmentary enlarged cross sectional view showing a bit line and a peripheral structure thereof for explaining the confinement effect of a magnetic field by the yoke cover in the embodiment;

FIG. 32 is a cross sectional view showing a memory cell in a semiconductor device according to a second embodiment of the invention;

FIG. 33 is a fragmentary enlarged cross sectional view showing a bit line and a peripheral structure thereof in the embodiment;

FIG. 34 is a cross sectional view showing a step of a manufacturing method of a semiconductor device in the embodiment;

FIG. 35 is a cross sectional view showing the structure of a sputtering chamber used in a step performed succeeding to the step shown in FIG. 34 in the embodiment;

FIG. 36 is a cross sectional view showing the state of a silicon nitride film after applying a treatment by the sputter chamber shown in FIG. 35 in the embodiment;

FIG. 37 is a cross sectional view showing a step which is performed succeeding to the step shown in FIG. 36 in the embodiment;

FIG. 38 is a cross sectional view showing a step which is performed succeeding to the step shown in FIG. 37 in the embodiment;

FIG. 39 is a cross sectional view showing a step which is performed succeeding to the step shown in FIG. 38 in the embodiment;

FIG. 40 is a cross sectional view showing a step which is performed succeeding to the step shown in FIG. 39 in the embodiment;

FIG. 41 is a cross sectional view showing a step which is performed succeeding to the step shown in FIG. 40 in the embodiment;

FIG. 42 is a table showing the result of XRR analysis in the embodiment;

FIG. 43 is a fragmentary enlarged cross sectional view showing a mixing layer, etc. in the embodiment;

FIG. 44 is a cross sectional view showing a memory cell in a semiconductor device according to a third embodiment of the invention;

FIG. 45 is a fragmentary enlarged cross sectional view showing a bit line and a peripheral structure thereof in the embodiment;

FIG. 46 is a cross sectional view showing a step of a manufacturing method of a semiconductor device in the embodiment;

FIG. 47 is a cross sectional view showing a step which is performed succeeding to the step shown in FIG. 46 in the embodiment;

FIG. 48 is a cross sectional view showing a step which is performed succeeding to the step shown in FIG. 47 in the embodiment;

FIG. 49 is a cross sectional view showing a step which is performed succeeding to the step shown in FIG. 48 in the embodiment;

FIG. 50 is a cross sectional view showing a step which is performed succeeding to the step shown in FIG. 49 in the embodiment;

FIG. 51 is a cross sectional view showing a step which is performed succeeding to the step shown in FIG. 50 in the embodiment;

FIG. 52 is a cross sectional view showing a step which is performed succeeding to the step shown in FIG. 51 in the embodiment;

FIG. 53 is a cross sectional view showing a memory cell in a semiconductor device according to a fourth embodiment of the invention;

FIG. 54 is a fragmentary enlarged cross sectional view showing a bit line and a peripheral structure thereof in the embodiment;

FIG. 55 is a cross sectional view showing a step of a manufacturing method of a semiconductor device in the embodiment;

FIG. 56 is a cross sectional view showing a step which is performed succeeding to the step shown in FIG. 55 in the embodiment;

FIG. 57 is a cross sectional view showing a step which is performed succeeding to the step shown in FIG. 56 in the embodiment;

FIG. 58 is a cross sectional view showing a step which is performed succeeding to the step shown in FIG. 57 in the embodiment;

FIG. 59 is a cross sectional view showing a step which is performed succeeding to the step shown in FIG. 58 in the embodiment; and

FIG. 60 is a cross sectional view showing a memory cell in a semiconductor device according to a modified example in each of the embodiments.

### DETAILED DESCRIPTION

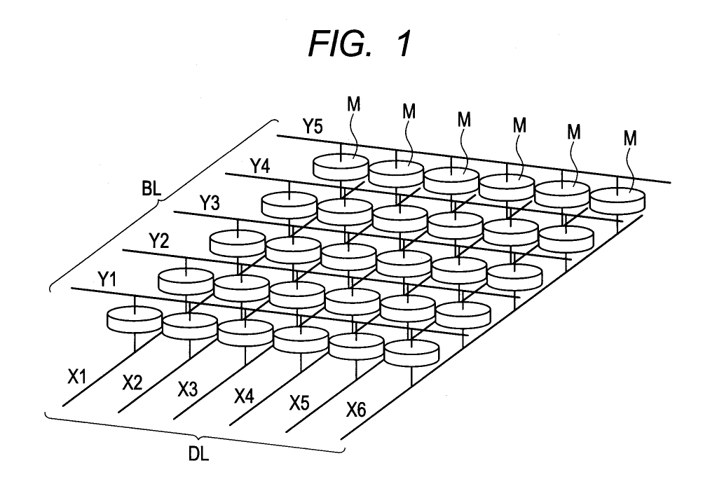

At first, the entire configuration of an MRAM as a semiconductor device is to be described. As shown in FIG. 1, magnetoresistive elements M in the MRAM are formed as an array arranged at intersections between digit lines DL extending in a first direction and bit lines BL extending in a second direction substantially perpendicular thereto.

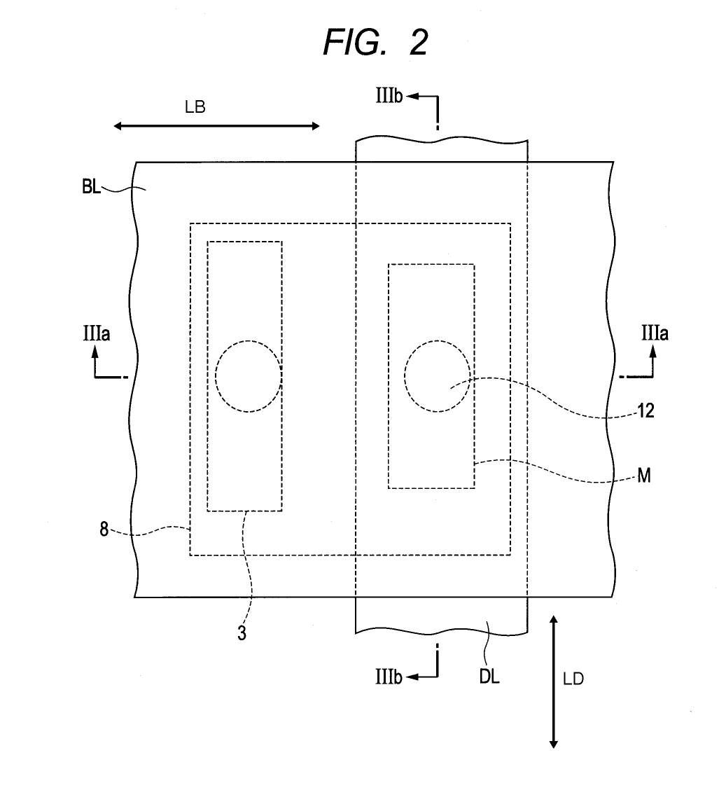

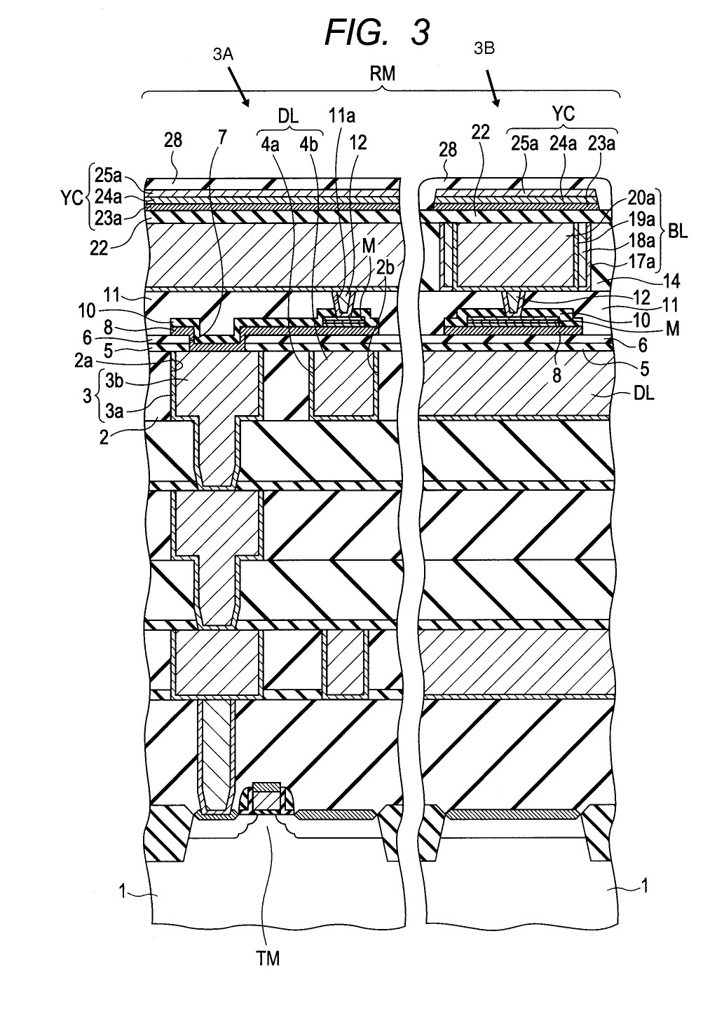

As shown in FIG. 2 and FIG. 3, in a memory cell region RM, one end of each magnetoresistive element M is electrically coupled by way of a top via 12 to a bit line BL, which extends along the direction indicated by double-headed arrow LB. On the other hand, the other end of the magnetoresistive element M is electrically coupled by way of a tantalum film 8, read interconnect 3, etc. to the drain region of an element selection transistor TM. The read interconnect 3 has an interconnect structure in which a copper film 3b is covered with a bather metal 3a. Further, each magnetoresistive element M is covered with a silicon nitride film 10. In FIG. 3, a cross sectional structure along a cross sectional line IIIa-IIIa of the cross sectional lines shown in FIG. 2 is depicted on the left of the drawing (indicated by “3A”), and a cross sectional structure along a cross sectional line IIIb-IIIb of the cross sectional lines shown in FIG. 2 is depicted on the right of the drawing (indicated by “3B”).

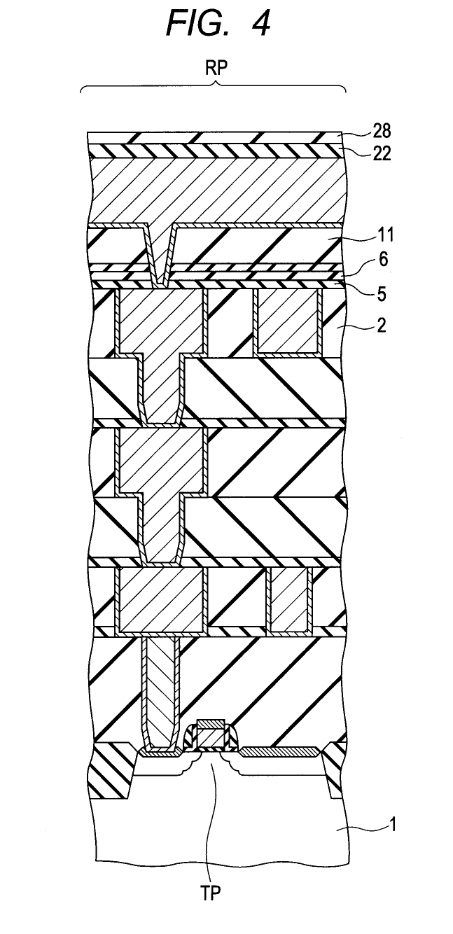

As shown in FIG. 4, in a peripheral circuit region RP, a semiconductor device such as a transistor TP for controlling the operation of a memory cell (magnetoresistive element), etc. and interconnects or via portions electrically coupling the semiconductor devices to each other are formed. For the peripheral circuit region, duplicate description for each of the embodiments is not described.

In each of the magnetoresistive elements M, two magnetic layers are laminated with a tunnel insulating film interposed therebetween. The resistance value of the magnetoresistive element M is changed by making the directions of magnetization in the two magnetic layers in an identical direction or directions opposite to each other. The direction of magnetization of the magnetoresistive element M is changed by a magnetic field generated by flowing a predetermined current to the bit line BL and the digit line DL which, as seen in FIG. 2, extends along the direction indicated by double-headed arrow LD. In MRAM, difference of the resistance value is utilized as information corresponding to “0” or “1”.

The digit line DL has an interconnect structure of covering a clad layer 4a having a function of shielding a magnetic field to a copper film 4b as an interconnect body. In the digit line DL arranged below the magnetoresistive element M by way of a silicon nitride film 5 and a silicon oxide film 6, the clad layer 4a is formed so as to cover the bottom and the side wall of the copper film 4b so as to inhibit magnetic field from exerting on regions other than the magnetoresistive element M arranged above.

On the other hand, the bit line BL has an interconnect structure of covering the copper film 20a with a clad layer 18a, etc. having a function of shielding a magnetic field. In the bit line BL arranged above the magnetoresistive element M, a clad layer 18a is formed so as to cover the lateral sides of the copper film 20a for inhibiting the magnetic field from exerting on regions other than the magnetoresistive element M arranged below. Further, in this semiconductor device, a yoke cover YC is formed so as to cover the upper surface of the bit line BL. In each of the embodiments, the structure of the yoke cover YC and the manufacturing method thereof are to be described specifically.

### First Embodiment

Now, description is to be made to an MRAM having a yoke cover including three layers of a bather metal layer as a first adhesion layer, a magnetic layer, and a bather metal layer as a second adhesion layer.

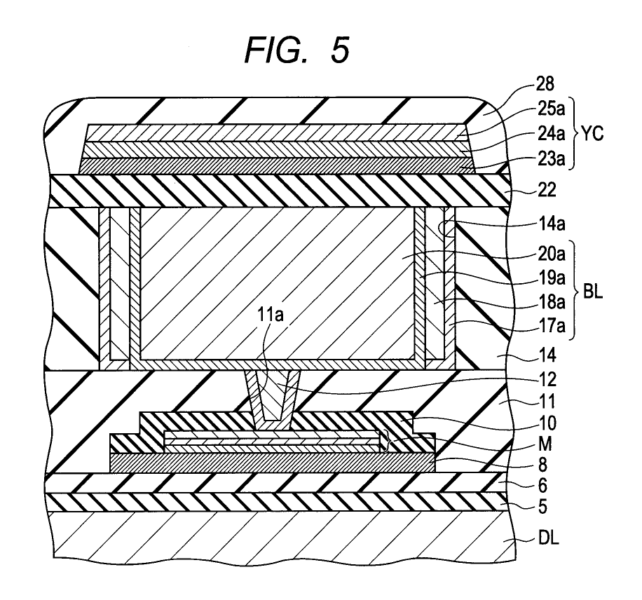

As shown in FIG. 5, the bit line BL is formed in an interconnect trench 14a engraved in a silicon oxide film 14. A clad layer 18a is formed being sandwiched between a bather metal 17a and a barrier metal layer 19a on the lateral side of a copper film 20a. A silicon nitride film 22 as an antidiffusion film for preventing copper of the copper film 20a from diffusion is formed in contact with the upper surface of the bit line BL.

The yoke cover YC is formed in contact with the upper surface of the silicon nitride film 22 so as to cover the upper surface of the bit line BL. The yoke cover YC is formed of a laminate film having a bather metal layer 23a as a lower adhesion layer of tantalum (Ta), etc., a magnetic layer 24a of nickel iron (NiFe), and a bather metal layer 25a as an upper adhesion layer of tantalum (Ta), etc. A silicon nitride film 28 as a cap layer is formed in contact with the surface of the yoke cover YC.

In this semiconductor device, the throughput can be improved and the production cost can be suppressed by forming the yoke cover YC by applying reactive ion etching to the laminate film when compared with the case of forming the yoke cover YC by applying CMP (Chemical Mechanical Polishing). Further, when the yoke cover YC is formed by reactive ion etching, the lamination facet of the laminate film forming the yoke cover YC is formed in a forward tapered shape. They are to be described later in details.

Then, the reason of requiring the barrier metal 23a as the lower adhesion layer and the barrier metal 25a as the upper adhesion layer for the yoke cover YC is to be explained. The silicon nitride film 28 is required for preventing a metal from diffusing from the magnetic layer 24a of the yoke cover YC and preventing oxidation of the magnetic layer 24a.

Generally, adhesion between a magnetic layer and an insulating film is extremely poor. Therefore, when the silicon nitride film 28 is formed directly to the magnetic layer 24a without the barrier metal 25a, peeling tends to occur at the boundary between the magnetic layer 24a and the silicon nitride film 28. Then, for preventing peeling of the silicon nitride film 28, the barrier metal 25a as the upper adhesion layer is required between the magnetic layer 24a and the silicon nitride film 28.

The barrier metal 25a is required to have good adhesion with both of the silicon nitride film 28 and the magnetic layer 24a. As the layer having such adhesion, high melting metal layers (films) of tantalum (Ta), titanium (Ti), tungsten (W), etc are usually suitable but they are not restricted to the high melting metal layer so long as they are layers (films) having adhesion as described above. Further, the high melting metal layer (film) of tantalum (Ta), etc. is formed by a sputtering method.

By the way, it has been known that the high melting metal layer (film) changes the volume and the membrane stress is changed when the layer is oxidized. For example, when the bather metal layer thereabove is exposed to the oxidative atmosphere by ashing upon removing a photoresist, the bather metal layer is oxidized and the membrane stress is changed. When the magnetic layer 24a is formed directly to the surface of the silicon nitride film 22, since the adhesion between the magnetic layer and the insulating film (silicon nitride film) is poor and the membrane stress of the barrier metal layer is changed, the yoke cover is sometimes peeled. Then, the barrier metal 23a as a lower adhesion layer is required between the magnetic layer 24a and the silicon nitride film 22 for preventing the yoke cover YC from peeling.

In this semiconductor device, the yoke cover YC is formed by applying reactive ion etching to the laminate film using the predetermined resist mask as an etching mask. When the resist mask is formed, it has to be aligned to the bit line BL.

Since the laminate film forming the yoke cover YC is a metal-containing film, when the thickness of the laminate film exceeds 50 nm, a light does not transmit therethrough and alignment cannot be performed. Accordingly, the laminate film is formed such that the sum of the thicknesses of the layers (thickness of the laminate film) is preferably 50 nm or less.

On the other hand, the laminate film is formed such that the thickness is preferably at least 10 nm or more in order to confine the magnetic field by the magnetic layer and ensure the function of the bather metal layer as an etching mask while securing adhesion between the bather metal layer and the silicon nitride film.

Further, as to be described later, the silicon nitride film 22 interposed between the bit line BL and the yoke cover YC is preferably formed to a thickness of about 150 nm or less in order to confine the magnetic field and concentrically exert the magnetic field to the magnetoresistive element M.

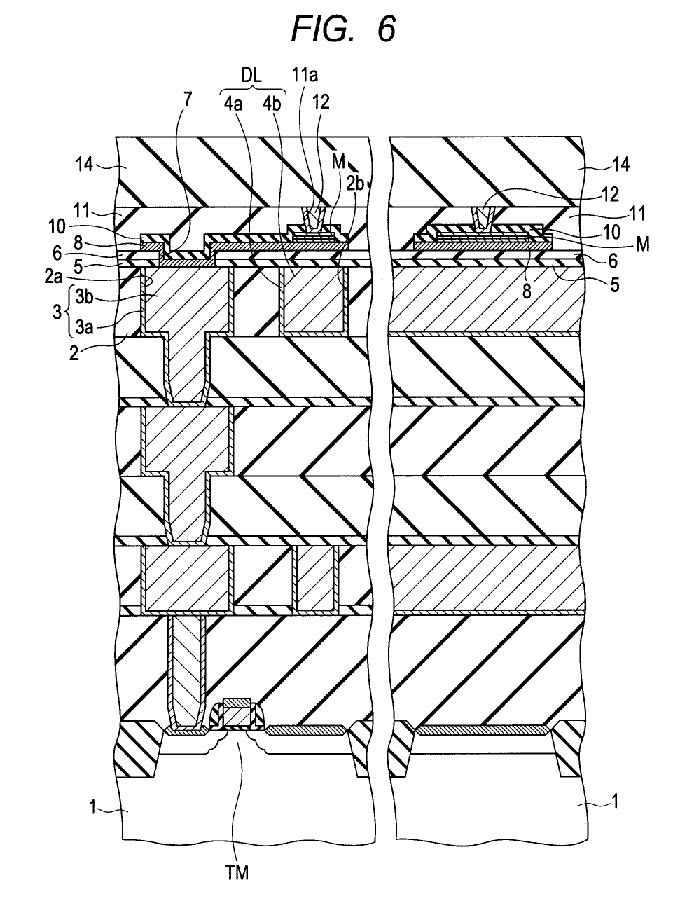

Then, a method of manufacturing the MRAM described above is to be described. At first, after forming the selection transistor TM, interconnects, vias, etc. over the surface of the semiconductor substrate 1 (refer to FIG. 3), a silicon oxide film 2 is formed as shown in FIG. 6. Interconnect trenches 2a and 2b are engraved to predetermined regions in the silicon oxide film 2. A read interconnect 3 having a clad layer 3a and a copper film 3b is formed in the interconnect trench 2a. A digit line DL comprising a clad layer 4a and a copper film 4b is formed in the interconnect trench 2b.

Then, a silicon nitride film 5 and the silicon oxide film 6 are formed on the silicon oxide film 2 so as to cover the digit line DL and the read interconnect 3. Then, an opening 7 for exposing the read interconnect 4 is formed penetrating the silicon oxide film 6 and the silicon nitride film 5. A tantalum (Ta) film as a metal strap (not illustrated) is formed over the silicon nitride oxide film 6 so as to cover the bottom and the side wall of the opening 7.

Then, a predetermined film as a pinned layer (not illustrated) is formed to the tantalum film 12. As the predetermined film, a laminate film comprising, for example, platinum (Pt), manganese (Mn), Nickel (Ni), ruthenium (Ru), cobalt (Co), iron (Fe), or boron (B) is formed. Then, a tunnel insulating film (not illustrated) is formed to a predetermined film as the pinned layer. For example, an aluminum oxide (AlOx) film, a magnesium oxide (MgO) film, or the like is formed as the tunnel insulating film.

Then, a predetermined film as a free layer is formed over the tunnel insulating film. As the predetermined film, an alloy film containing at least two metals, for example, of nickel (Ni), iron (Fe), cobalt (Co), and boron (B) is formed. Then, a predetermined film as a cap layer (not illustrated) is formed over the predetermined film as the free layer. A ruthenium (Ru) film is formed, for example, as the predetermined film as the cap layer. A tantalum (Ta) film (not illustrated) is formed over the predetermined film as the cap layer.

Then, a resist pattern (not illustrated) for patterning the magnetoresistive element is formed over the tantalum (Ta) film. Then, a magnetoresistive element M is formed as shown in FIG. 6 by applying etching under predetermined conditions to the tantalum (Ta) film, the predetermined film as the cap layer, the predetermined film as the free layer, the tunnel insulating film, and the predetermined film as the pinned layer by using the resist pattern as a mask.

Then, a silicon nitride film as a liner film (not illustrated) is formed so as to cover the magnetoresistive element M. Then, a resist pattern (not illustrated) for patterning the metal strap is formed over the silicon nitride film. Then, a tantalum film 8 as the metal strap and a silicon nitride film 10 as the liner film are formed as shown in FIG. 6 by applying etching under predetermined conditions to the silicon nitride film and the tantalum (Ta) film by using the resist pattern as a mask.

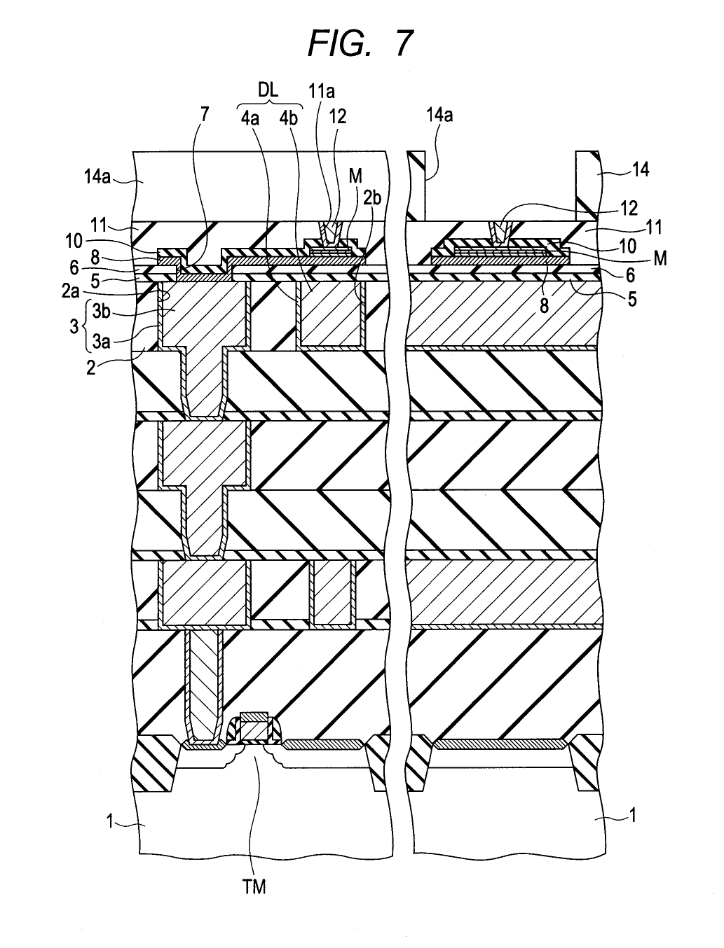

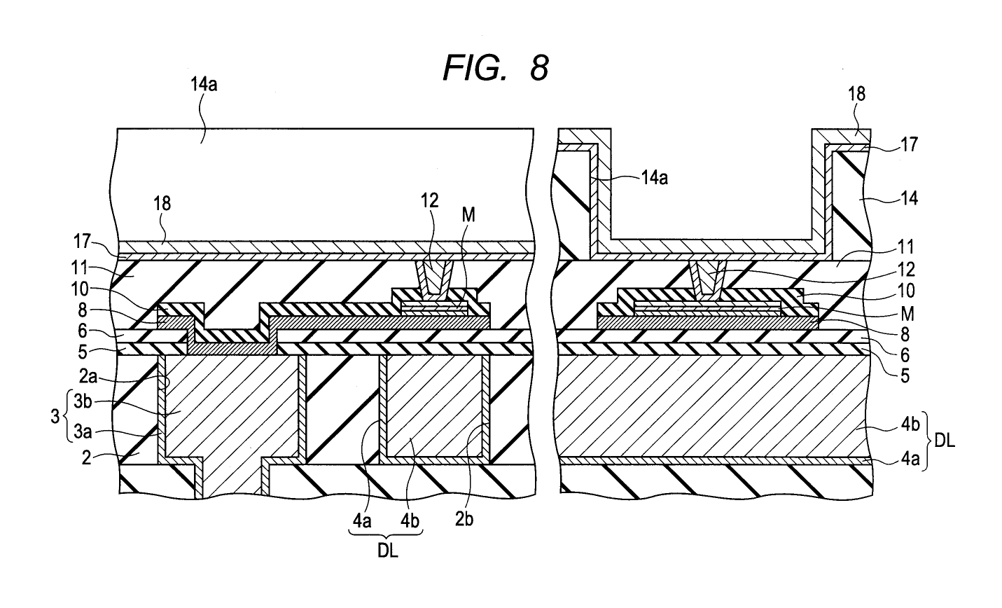

Then, a silicon oxide film 11 is formed so as to cover the magnetoresistive element M. An opening 11a for exposing the surface of the magnetoresistive element M is formed in the silicon oxide film 11, and a top via is formed in the opening 11a. Then, a silicon oxide film 14 is formed so as to cover the top via 11a. Then, as shown in FIG. 7, an interconnect trench 14a for forming the bit line is engraved in the silicon oxide film 14. Then, as shown in FIG. 8, a bather metal layer 17, for example, of tantalum (Ta) is formed so as to cover the bottom and the lateral sides of the interconnect trench 14a. Then, a magnetic layer 18, for example, of nickel iron (NiFe) is formed as a clad layer for shielding the magnetic field over the barrier metal layer 17.

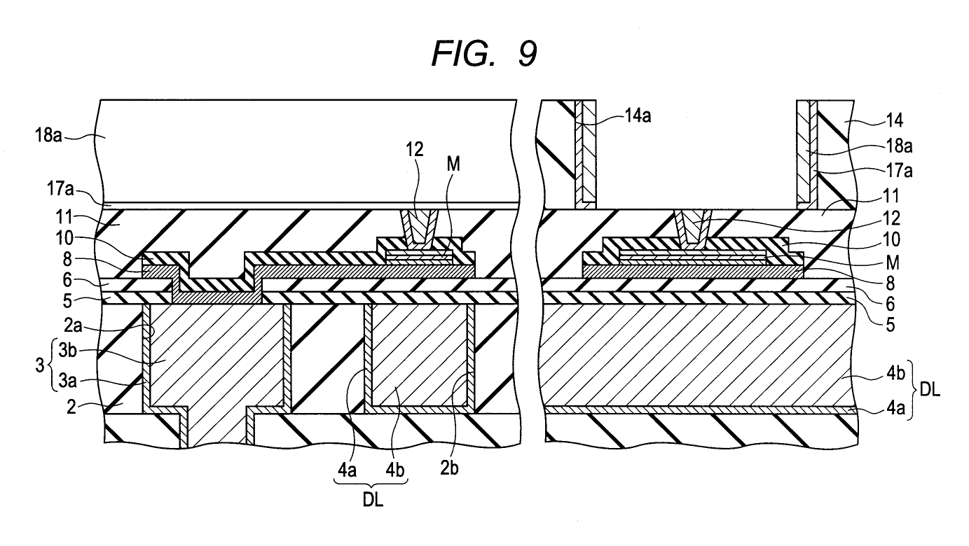

Then, by applying etching or sputter etching to the magnetic layer 18 and the barrier metal 17, a portion of the magnetic layer 18 and the bather metal 17 arranged at the bottom of the interconnect trench 14a and the upper surface of the silicon oxide film 14 are removed while leaving each of the portions of the magnetic layer 18 and the barrier metal 17 arranged on the lateral sides of the interconnect trench 14a (magnetic layer 18a, barrier metal 17a) as shown in FIG. 9. In this etching, a portion of the barrier metal layer arranged at the bottom of the interconnect trench 14a may be left but a portion of the magnetic layer 18 should be removed completely.

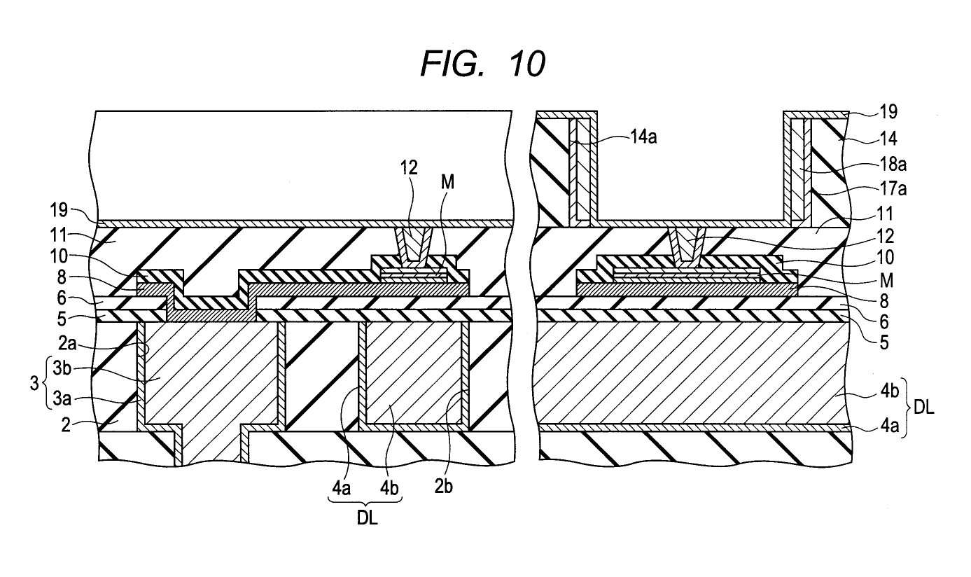

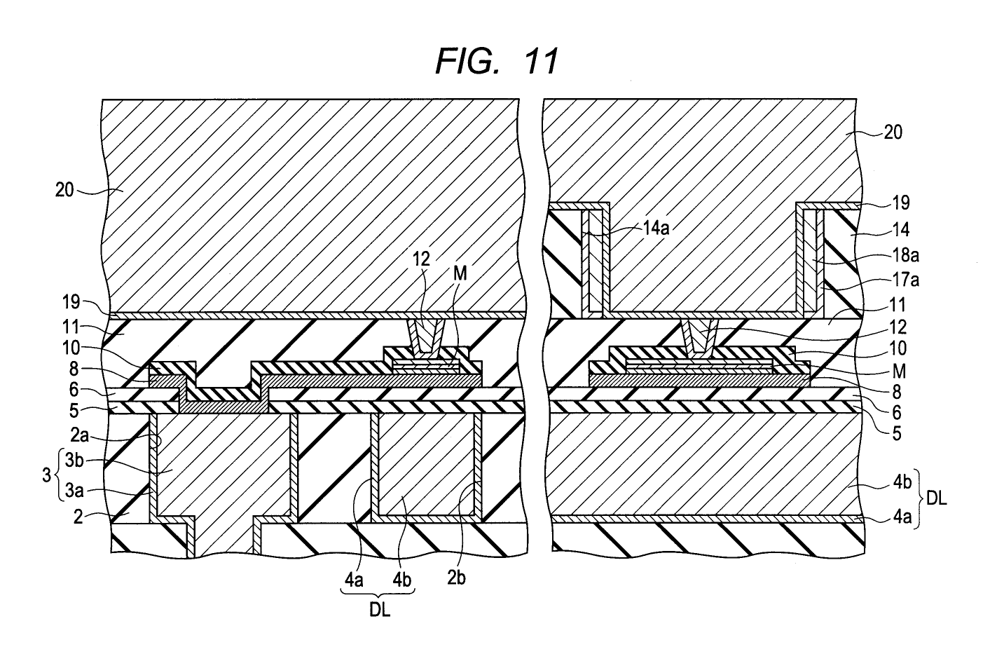

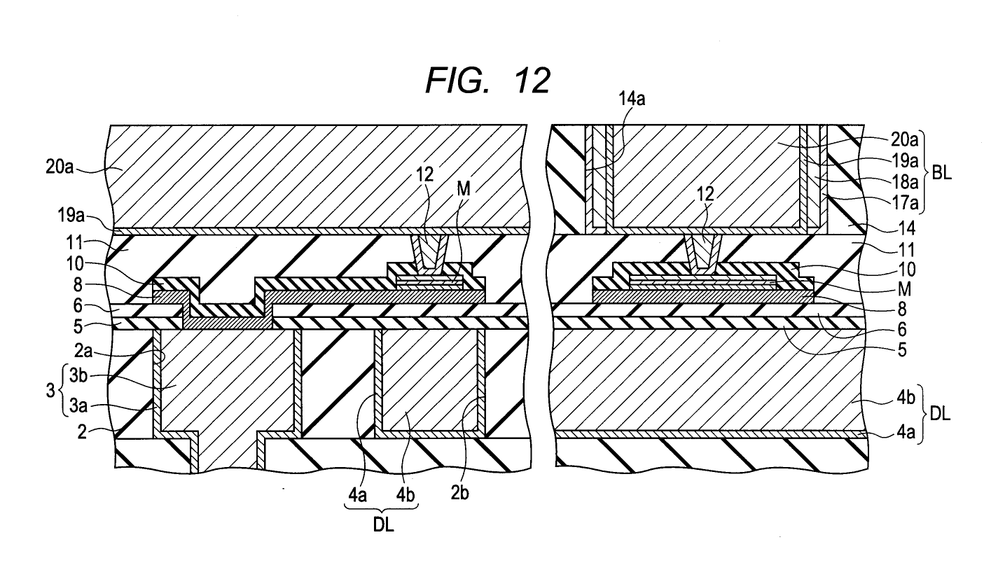

Then, as shown in FIG. 10, a barrier metal layer 19, for example, of tantalum (Ta) is formed so as to cover the bottom of the interconnect trench 14a, etc. by a sputtering method. Then, a copper film 20 is formed by plating so as to fill the interconnect trench 14a as shown in FIG. 11. Then, as shown in FIG. 12, by removing portions of the bather metal 19 and the copper film 20 arranged above the upper surface of the silicon oxide film 14 by performing the chemical mechanical polishing, portions of the barrier metal layer 19 and the copper film 20 left in the interconnect trench 14a (bather metal 19a, copper film 20a) are formed as the bit line BL.

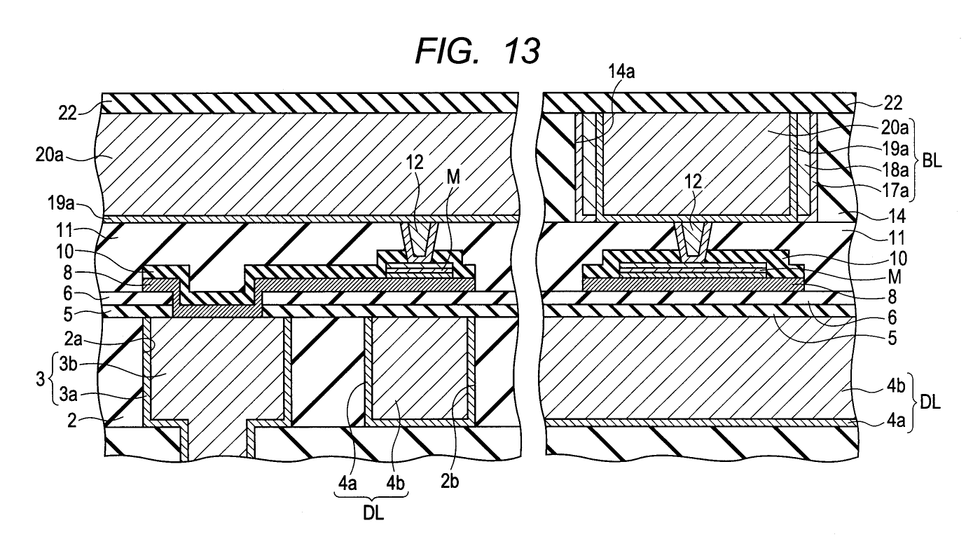

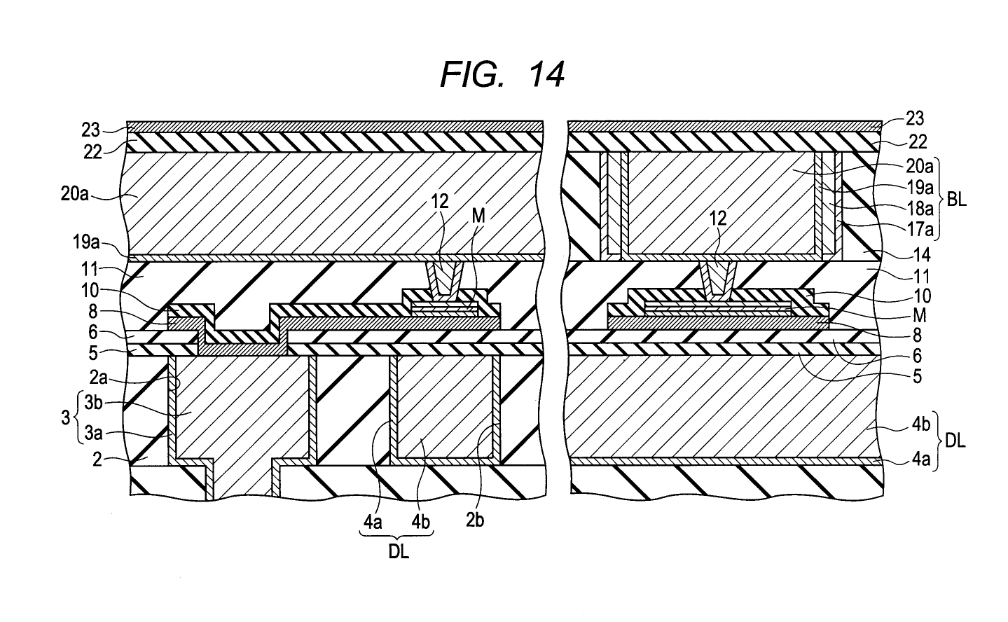

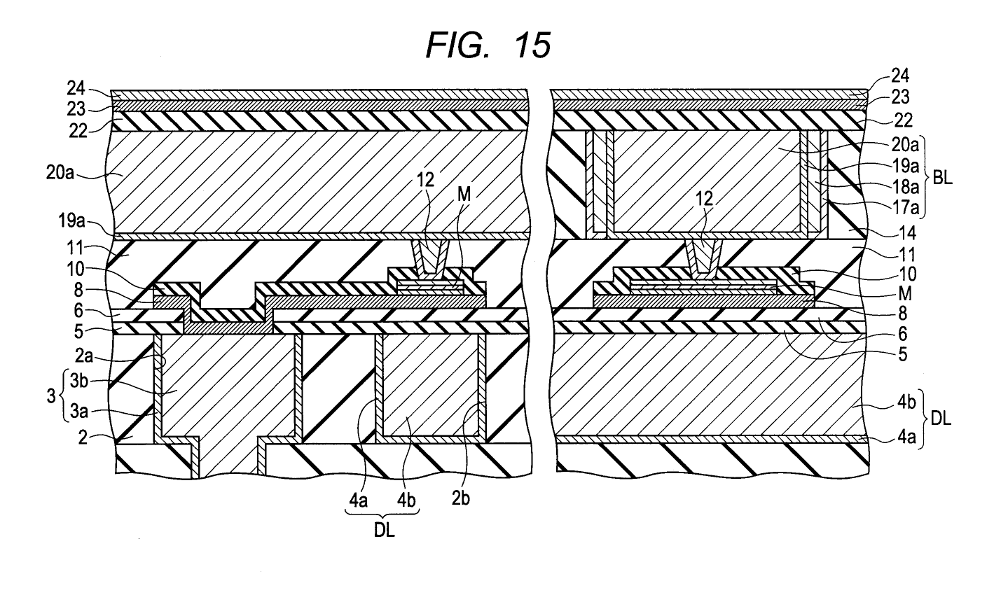

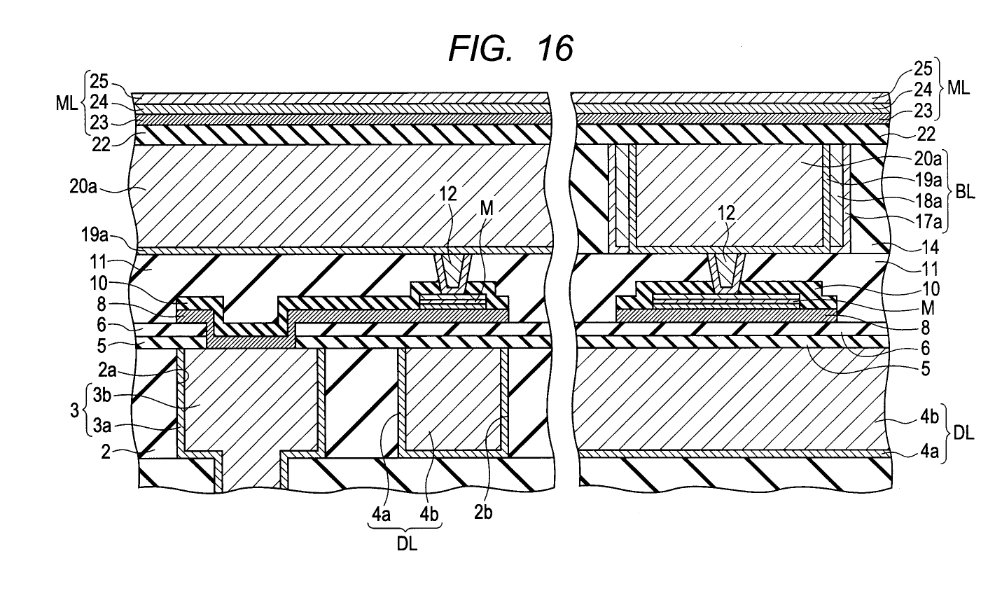

Then, as shown in FIG. 13, a silicon nitride film 22 as an antidiffusion film for the interconnect material that prevents the copper material in the copper film 20a of the bit line BL from diffusing is formed in contact with the upper surface of the bit line BL. Then, a laminate film forming the yoke cover is formed successively. At first, as shown in FIG. 14, a barrier metal layer 23 as a lower adhesion layer of about 5 nm thickness, for example, of tantalum (Ta) is formed in contact with the surface of the silicon nitride film 22 by a sputtering method. Then, as shown in FIG. 15, a magnetic layer 24 of about 15 nm thickness, for example, of nickel iron (NiFe), etc. for shielding a magnetic field is formed in contact with the surface of the barrier metal 23 by a sputtering method. Then, as shown in FIG. 16, a barrier metal layer 25 as an upper adhesion layer of about 15 nm thickness, for example, of tantalum (Ta), etc. is formed in contact with the surface of the magnetic layer 24 by a sputtering method. Thus, a laminate film ML as the yoke cover is formed.

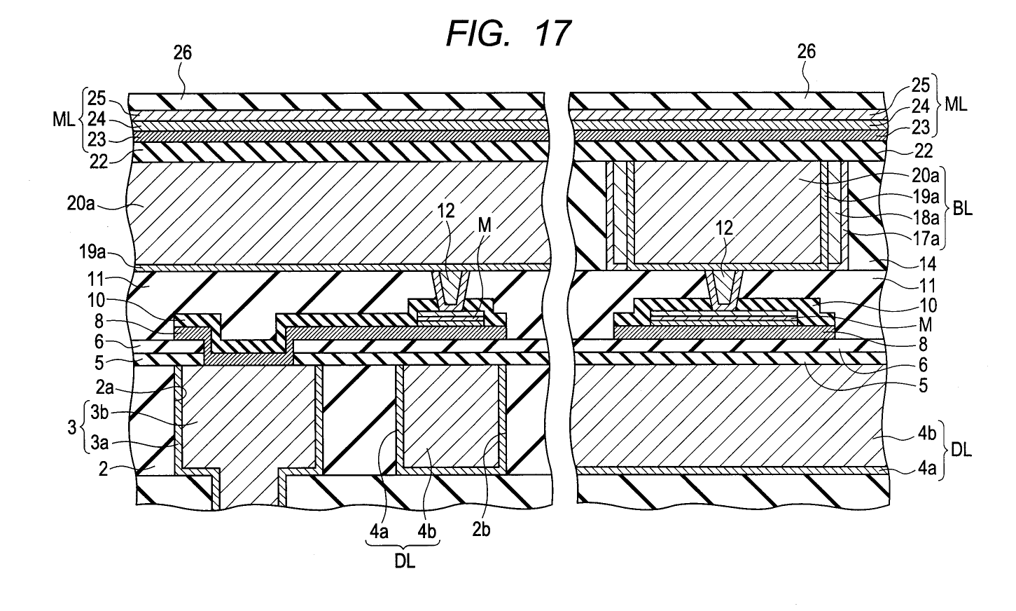

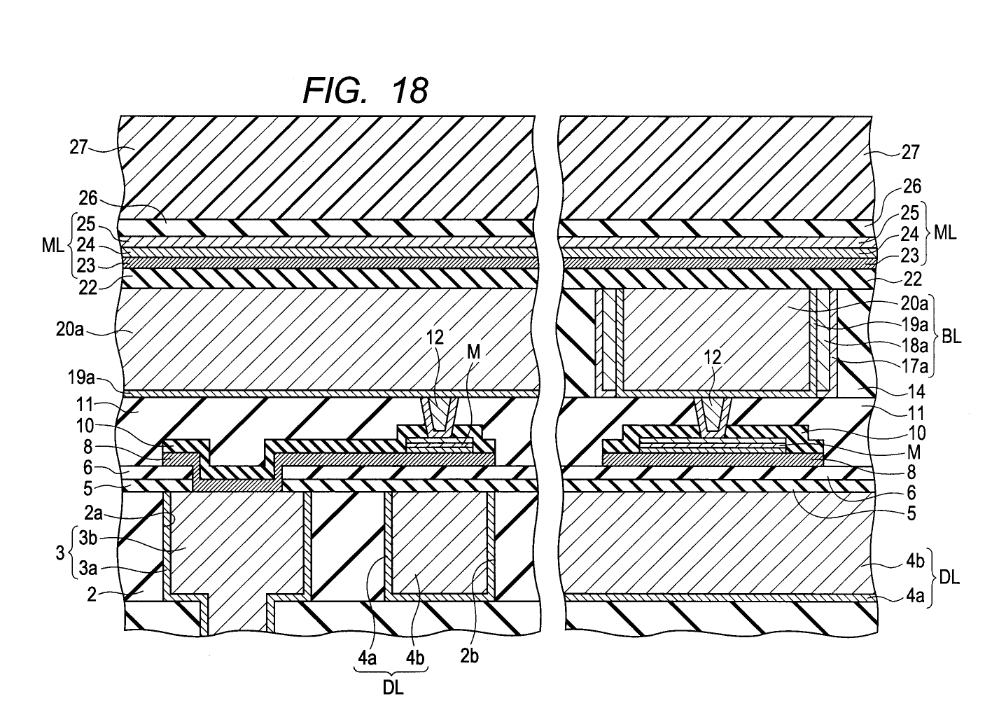

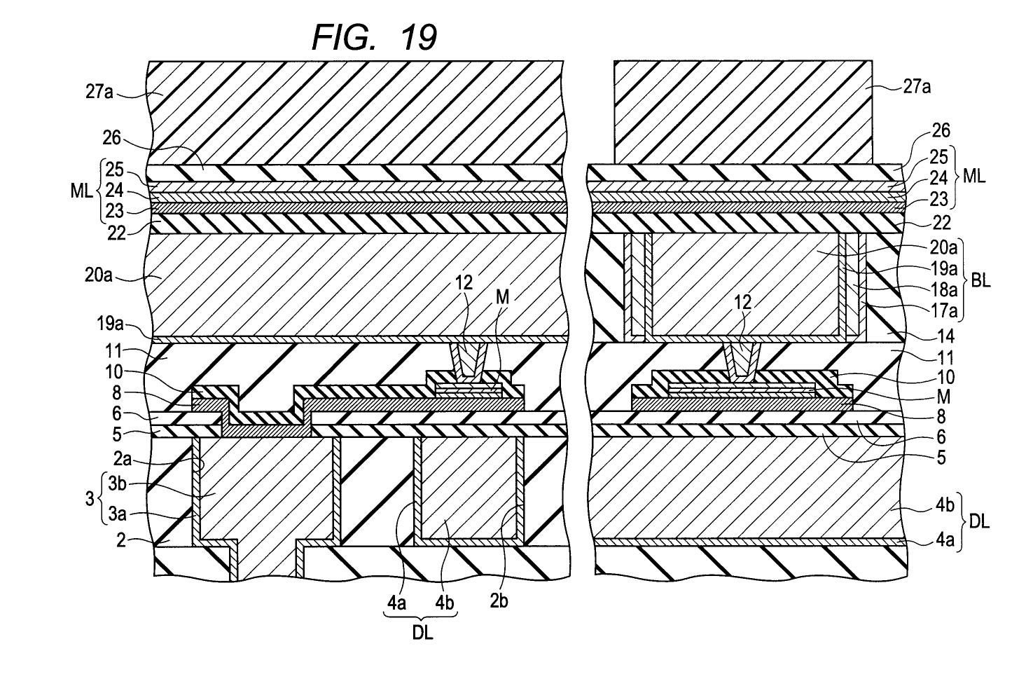

Then, photoengraving for patterning the laminate film ML (23, 24, 25) is applied. As shown in FIG. 17, an organic antireflection film 26 is formed on the surface of the barrier metal layer 25. Then, as shown in FIG. 18, a photoresist 27 is coated on the surface of the antireflection film 26. Then, photoengraving is applied to the photoresist 27 thereby forming a resist mask 27a for patterning the yoke cover as shown in FIG. 19. The resist mask 27a is formed along the bit line BL so as to cover the bit line BL.

Then, the laminate film ML (23, 24, 25) is patterned. At first, reactive ion etching is applied to the antireflection film 26 and the barrier metal 25 in an atmosphere of a gas mixture, for example, of a carbon tetrafluoride (CF₄) gas and an argon (Ar) gas by using the resist mask 27a as an etching mask thereby forming a mask (not illustrated) of the barrier metal layer 25 (step 1). Then, the resist mask 27a is removed and reactive ion etching is applied to the magnetic layer 24 in an atmosphere of a gas mixture, for example, of carbon monoxide (CO), an ammonia (NH₃) gas, and an argon (Ar) gas by using the mask of the barrier metal layer 25 as an etching mask thereby patterning the magnetic layer 24 (step 2). Then, reactive ion etching is applied to the barrier metal layer 23 in an atmosphere of a gas mixture, for example, of a carbon tetrafluoride (CF₄) gas and an argon (Ar) gas by using the mask of the barrier metal layer 25 as an etching mask thereby pattering the barrier metal layer 23 (step 3).

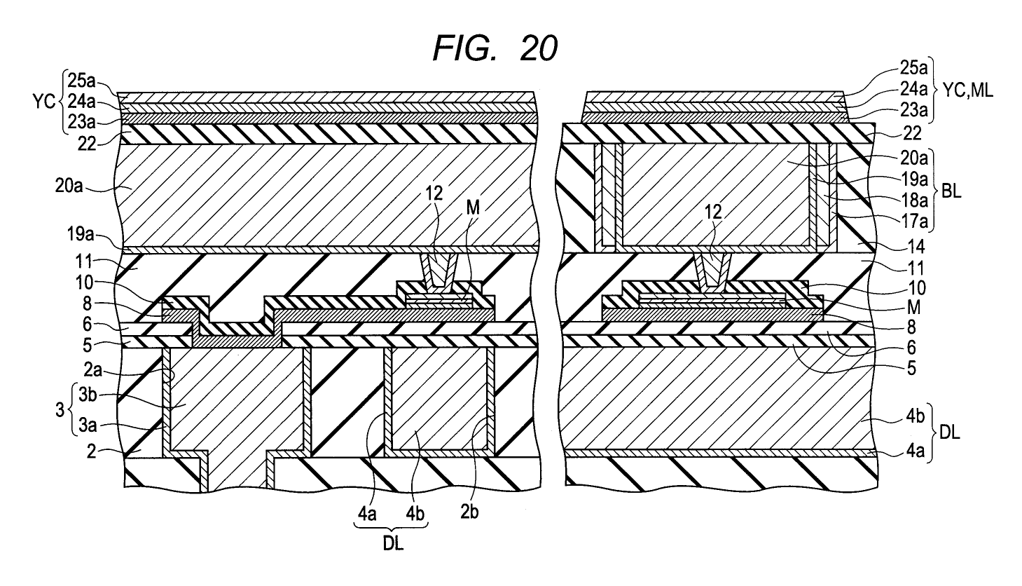

As described above, by patterning the laminate film ML (23, 24, 25), a yoke cover YC having a bather metal layer 23a, a magnetic layer 24a, and a barrier metal layer 25a is formed as shown in FIG. 20. Subsequently, a silicon nitride film 28 is formed in contact with the surface of the yoke cover YC thereby forming a main portion of the MRAM as shown in FIG. 5.

In the method of manufacturing the MRAM described above, the production cost can be suppressed while improving the throughput by applying reactive ion etching to the predetermined laminate film including the magnetic layer thereby forming the yoke cover YC. This is to be described also with reference to comparative examples.

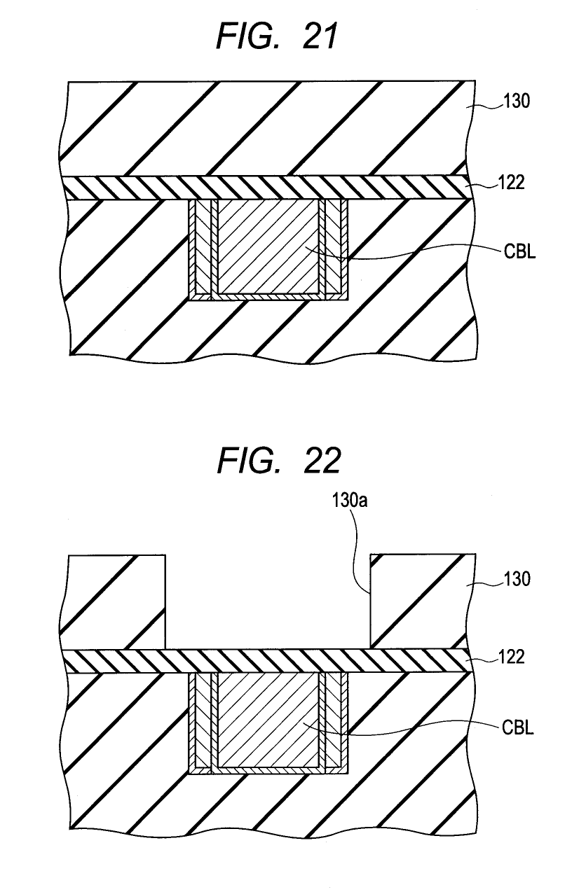

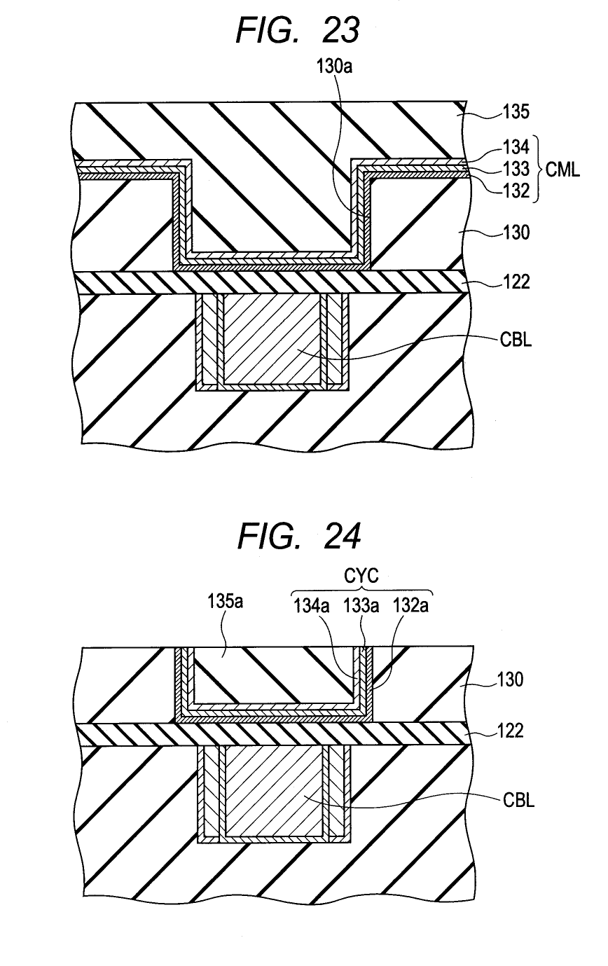

As shown in FIG. 21, after forming a silicon nitride film 122 as an antidiffusion film in contact with the upper surface of a bit line CBL, a silicon oxide film 130 is formed by an HDP (High Density Plasma) method. Then, as shown in FIG. 22, a trench 130a is formed to the silicon oxide film 130 along the bit line CBL so as to expose the surface of the silicon nitride film 112. Then, as shown in FIG. 23, a bather metal layer 132, a magnetic layer 133, and a barrier metal 134 are formed successively over the surface of the silicon oxide film 130 so as to cover the bottom and the lateral sides of the trench 130a. Thus, the laminate film CML as the yoke cover is formed. Then, a silicon oxide film 135 is formed on the surface of the laminate film CML so as to fill the trench 130a by a high density plasma method.

Then, chemical mechanical polishing is applied and, while leaving the portion of the laminate film CML (132a, 133a, 134a) arranged at the bottom and the lateral side near the bottom of the trench 130a, other portions of the laminate film CML and the silicon oxide film 135 are removed (refer to FIG. 24). Thus, the yoke cover CYC is formed as shown in FIG. 24.

In the semiconductor device according to the comparative example, two steps of forming the silicon oxide films (silicon oxide film 130, 135) by the high density plasma method are required for forming the yoke cover CYC and, further, a step of applying chemical mechanical polishing to the laminate film CML as the yoke cover and the silicon oxide film 135 are required. Accordingly, compared with the steps of forming the yoke cover in the MRAM described above, the number of steps is increased more which causes hindrance in the reduction of the production cost.

Further, in the chemical mechanical polishing, since the amount of polishing varies within the plane of a wafer (semiconductor substrate), it is necessary to form a silicon oxide film having an adequate thickness as the silicon oxide film for decreasing the effect due to the variation of the polishing amount and, further, it is necessary to form a trench of an adequate depth as the trench, which may lower the throughput.

On the contrary, in the MRAM described above, the yoke cover YC is formed, after forming the silicon nitride film 22, by forming the predetermined laminate film ML and applying reactive ion etching to the laminate film ML. Accordingly, the number of steps is smaller compared with that in the comparative example, which can contribute to the reduction of the production cost. Further, since the yoke cover YC is substantially formed by the patterning of the laminate film by reactive ion etching, the process is simple as that for forming the yoke cover, which can improve the throughput.

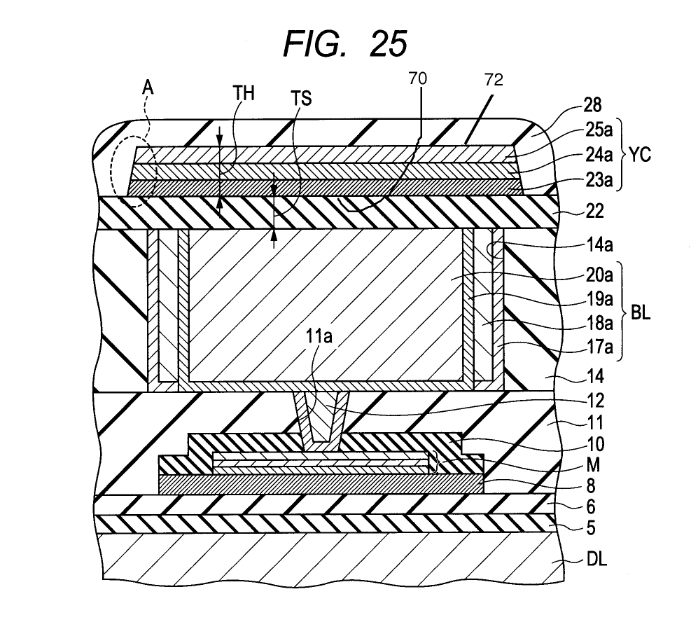

Then, the thickness TH of the yoke cover YC, the thickness TS of the underlying silicon nitride film 22 and the shape for the lamination facet of the yoke cover YC (shown in a dotted frame) are to be described with reference to FIG. 25. At first, the thickness of the yoke cover YC is to be described.

For patterning the laminate film by reactive ion etching, it is necessary to form a resist mask. In the photoengraving upon forming the resist mask (refer to FIG. 19), it is necessary for alignment with the underlying pattern based on an alignment mark. In the MRAM, the alignment mark is formed by a damascene method upon formation of the bit line simultaneously. Accordingly, since there is no step as the alignment mark, the alignment mark can be detected by transmitting a light after forming the laminate film.

However, since the laminate film comprises the barrier metal (Ta) layer and the magnetic layer (NiFe) and is not a transparent film, when the thickness of the laminate film is increased, detection of the alignment mark formed to the underlayer of the laminate film is sometimes difficult. Accordingly, there may be a possibility that the photoengraving for the photoresist mask cannot be performed satisfactory, for example, by erroneous detection for the alignment mark.

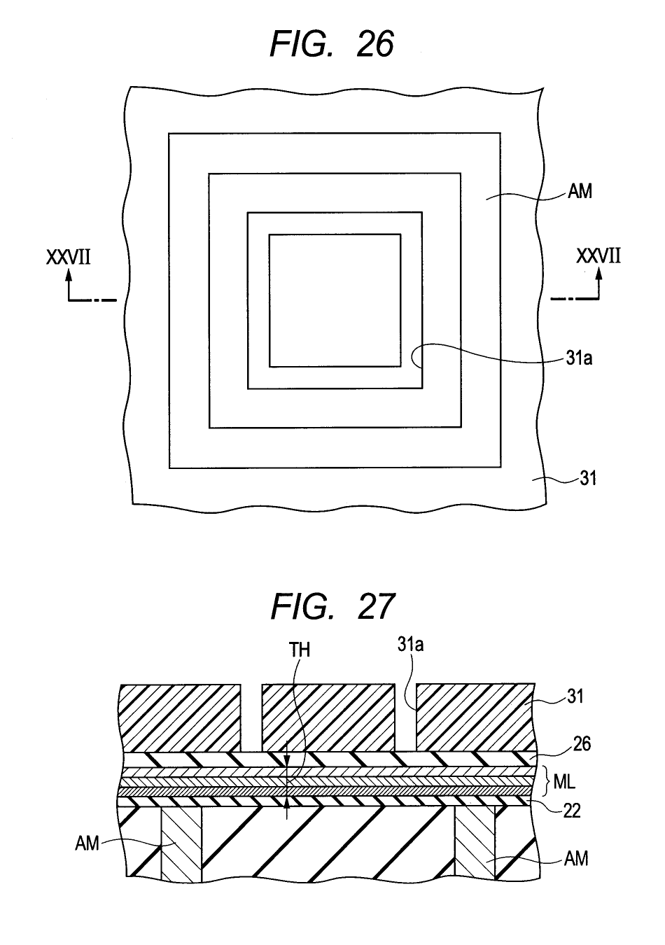

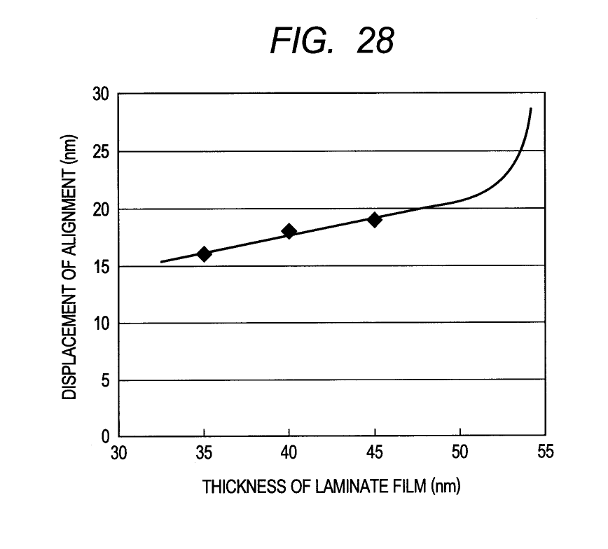

Then, the present inventors have evaluated a relation between the thickness of the laminate film as the yoke cover and the displacement of alignment. As a specimen for evaluation, a specimen in which rectangular alignment mark AM formed of a copper film is formed in a dicing line region was provided and the thickness TH of the laminate film ML was allocated as shown in FIG. 26 and FIG. 27. Further, a rectangular blank pattern 31a was formed for focusing in the photoresist 31 coated on the laminate film ML. Misalignment was evaluated by alignment using the alignment mark AM arranged below the laminate film ML in a state of focusing to the photoresist 31. The result is shown in FIG. 28.

FIG. 28 is a graph showing a relation between the displacement of alignment (on the ordinate) and the thickness of the laminate film (on the abscissa). As shown in the graph, it can be seen that a light for alignment can transmit the laminate film and the displacement of alignment was relatively small at a thickness of the laminate film of about 50 nm or less. On the other hand, it has been found that the light cannot transmit the laminate film, and the displacement of alignment increased abruptly when the thickness of the laminate film exceeds about 50 nm. In view of the result of the evaluation, it has been found that the thickness of the laminate film is preferably set to 50 nm or less.

Further, according to the evaluation of the inventors, et al, it has been found that it is difficult to confine the magnetic field when the thickness of the magnetic layer 24a is less than 5 nm in the yoke cover YC. Therefore, it has been found that the thickness of the magnetic layer 24a is preferably set to 5 nm or more for obtaining a desired characteristic as the MRAM. Further, it has been found that adhesion with the underlying silicon nitride film can be ensured when the thickness of the barrier metal layer 23a is 1 nm or more. Further, it has been found that the thickness of the barrier metal layer 25a is preferably set about identical with that of the magnetic layer in order to ensure the function and the etching mask upon applying reactive ion etching. In view of the result of the evaluation, it has been found that the laminate film is preferably formed to at least 10 nm or more.

In view of the result of the evaluation described above, the thickness TH of the yoke cover YC formed by patterning the laminate film is 10 nm or more and 50 nm or less.

Then, the thickness TS of the silicon nitride film 22 is to be described. As the thickness of the silicon nitride film 22 interposed between the bit line BL and the yoke cover YC is decreased, the yoke cover YC can be brought closer to the upper surface of the bit line BL thereby decreasing the magnetic field leaked through a portion between the bit line BL and the yoke cover YC.

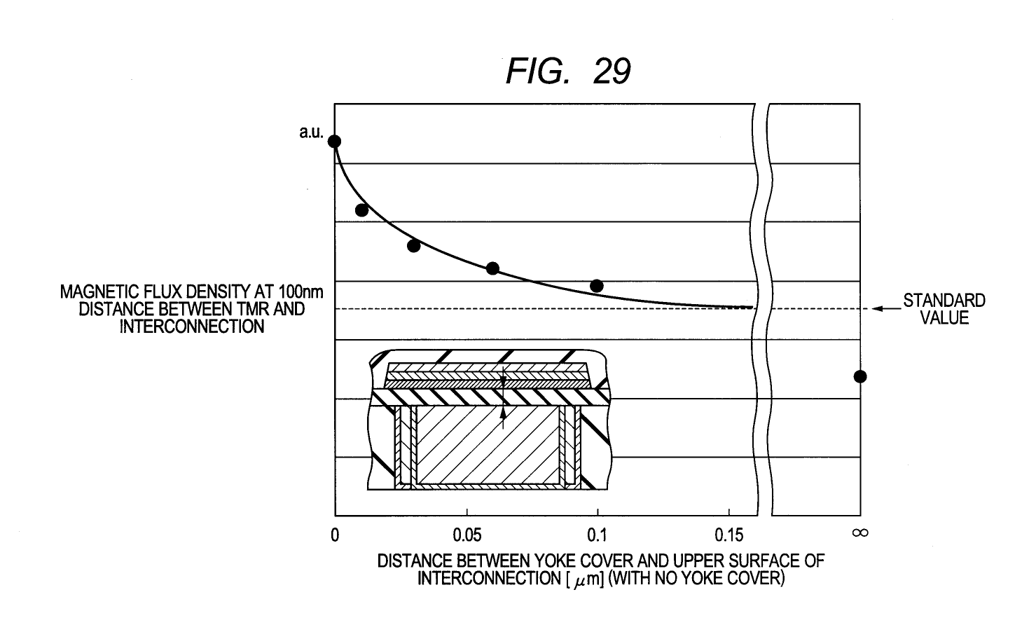

FIG. 29 is a graph showing a relation between the magnetic flux density (coercivity) and the thickness of the silicon nitride film evaluated by the inventors, et al. The abscissa shows a distance between the yoke cover and the upper surface of the bit line which corresponds to the thickness of the silicon nitride film. The ordinate shows a magnetic flux density (coercivity) when the distance between the magnetoresistive element and the bit line is set to 100 nm. Standard values shown in the graph shows a lower limit of the magnetic flux density (coercivity) capable of stably magnetizing the magnetoresistive element (coercivity). According to the graph, it can be seen that a magnetic field can be confined and can be exerted concentrically to the magnetoresistive element M when the distance between the yoke cover and the upper surface of the bit line, that is, the thickness of the silicon nitride film is 150 nm or less. In MRAM described above, the standard thickness of the silicon nitride film was set to about 60 nm.

Then, the shape of the lamination facet of the laminate film of the yoke cover YC is to be described. In the MRAM described above, the yoke cover YC is formed by applying three steps of etching treatment, to the laminate film ML, which includes reactive ion etching with a gas mixture of a carbon tetrafluoride (CF₄) gas and an argon (Ar) gas (step 1), reactive ion etching with a gas mixture of a carbon monoxide (CO), an ammonia (NH₃) gas, and an argon (Ar) gas (step 2), and reactive ion etching with a gas mixture of a carbon tetrafluoride (CF₄) gas and an argon (Ar) gas (step 3).

According to the evaluation made by the inventors, it has been confirmed that the facet of the yoke cover YC patterned by the three steps of reactive ion etching is in a forward tapered shape. That is, as shown in FIG. 25 (in dotted frame A), it has been found that the yoke cover YC is formed such that two opposing lamination facets of the laminate film ML intersect the surface of the underlying silicon nitride film 22 in a manner that they approach to each other in the upward direction. In other words, the yoke cover facets which extend along the length direction LB of bit line BL, are forward tapered. Thus, in a cross-sectional view of the semiconductor device taken transverse to the length direction LB of the bit line BL as seen in FIG. 25, the yoke facets converge in a direction away from the bit line BL. Alternatively, one may say that, along the length direction of the bit line, the yoke cover (and thus, the laminate film ML) has a tapered shape and is wider closer to the bit line (such as at its base portion 70) and narrower farther from the bit line (such as at its top portion 72. Also, as seen in FIG. 5, facets of the individual layers constituting the laminate film ML, (i.e., the lower barrier metal film 23a, the magnetic layer 24a and the upper barrier metal film 25a), may be individually tapered, with the taper being contiguous between adjacent layers. Thus, two or more of the contiguous lower adhesion layer, the magnetic layer and the upper adhesion layer (and also the hard mask layer described below) together have a tapered shape and converge in a direction away from the bit line BL, i.e., they are wider closer to the bit line and narrower farther from the bit line.

On the other hand, in the MRAM according to the comparative example, as shown in FIG. 24, since the yoke cover is formed by chemical mechanical polishing, the lamination facets of the yoke cover are arranged on a plane identical with the upper surface of the silicon oxide film 130 and do not intersect the surface of the underlying silicon nitride film 122.

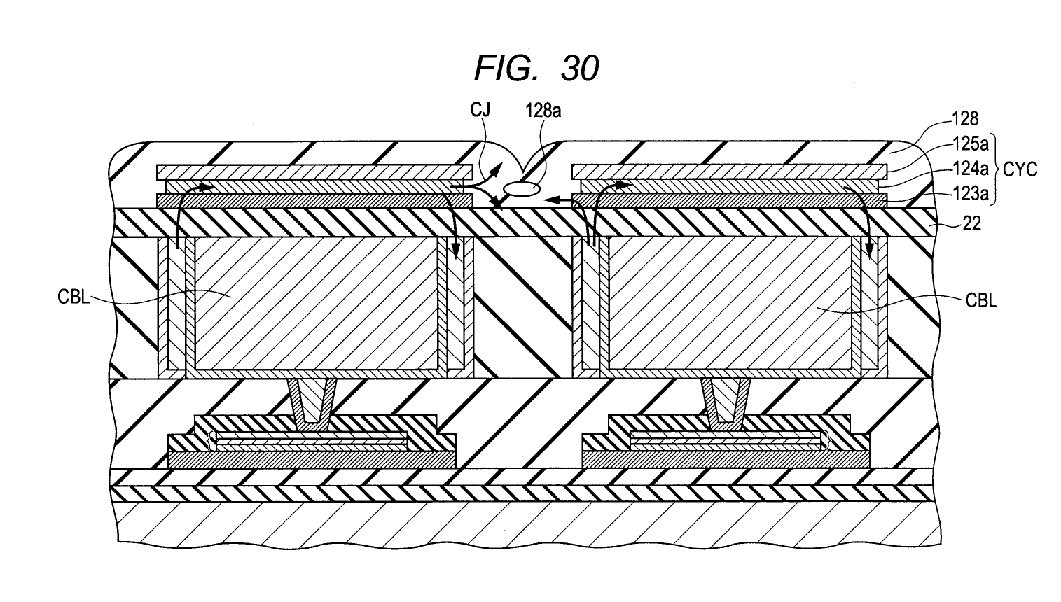

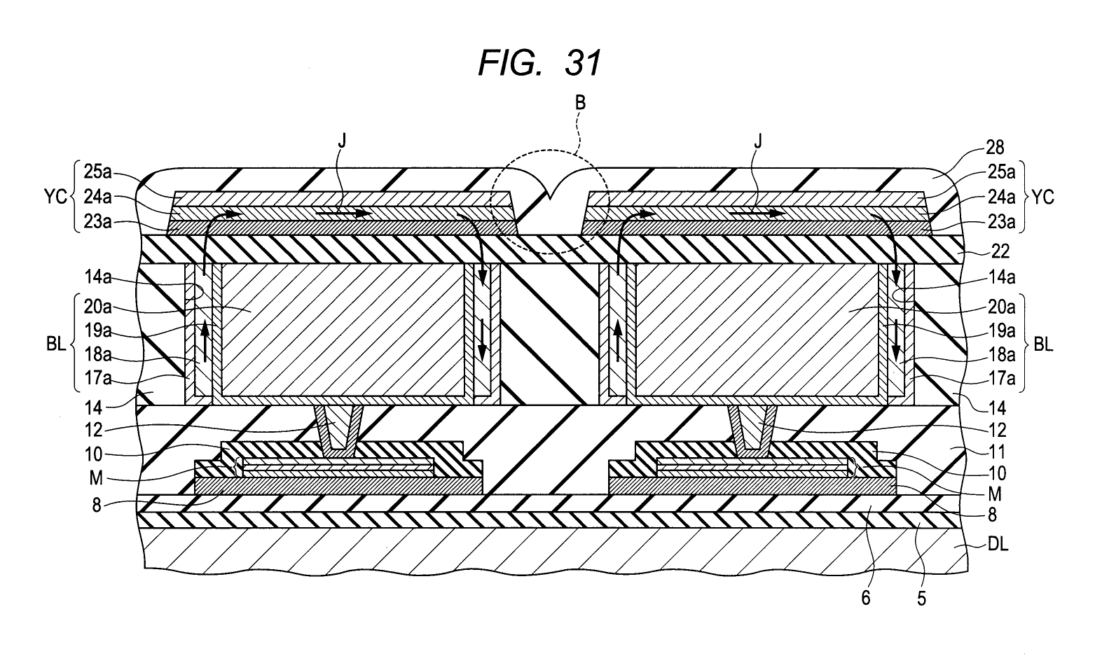

Since the lamination facets of the yoke cover YC are in the forward tapered shape as shown in FIG. 25, coverage with the silicon nitride film 28 as the antidiffusion film that covers the yoke cover YC is also improved. Generally, in the laminate film, the magnetic layer tends to be etched more than the bather metal layer. Accordingly, side etching may be generated in the lamination facet of the yoke cover CYC due to the retraction of the facet of the magnetic layer 124a further from the facet of the barrier metal layers 123a, 125a as shown in FIG. 30. When the silicon nitride film 128 is formed in a state where side etching is present at the lamination facet of the yoke cover CYC, a region arranged between the yoke covers which are adjacent to each other cannot be buried properly by the silicon nitride film and result in a void 128a. Accordingly, the magnetic field may possibly be leaked as shown in an arrow CJ.

On the other hand, in the yoke cover YC having the lamination facet in the forward tapered shape as shown in FIG. 31, a region arranged between the yoke covers YC which are adjacent to each other (shown in dotted frame B) can be buried properly with the silicon nitride film 28 and formation of voids in the silicon nitride film 28 can be suppressed. In addition, since the lamination end face is formed in the forward tapered shape, the longitudinal size of the yoke cover YC can be increased without lowering the exposure margin upon forming the resist mask. That is, the width of the yoke cover YC can be extended without narrowing the distance between the resist masks adjacent to each other in the direction perpendicular to the extending direction of the bit line (digit line extending direction). This can improve the overlap margin between the bit line BL and the yoke cover YC and the leakage of the magnetic field can be suppressed effectively to confine the magnetic field as shown by arrows J in FIG. 31.

### Second Embodiment

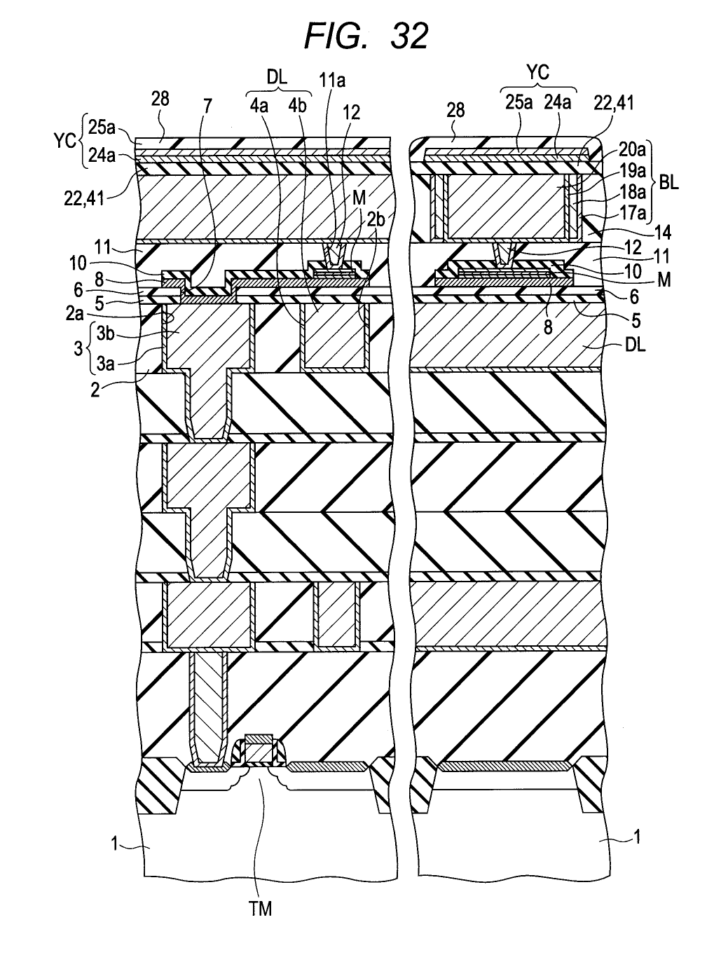

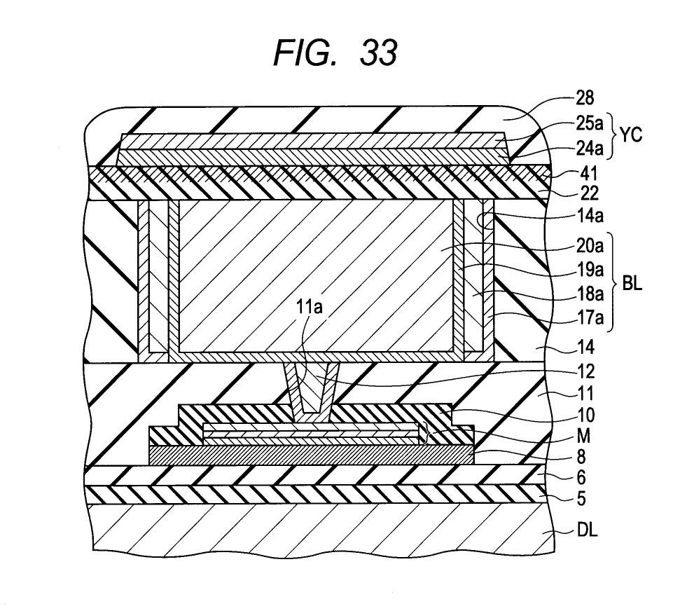

An MRAM having a yoke cover of two layers including a magnetic layer and an upper barrier metal layer is to be described. As shown in FIG. 32 and FIG. 33, the yoke cover YC covering the upper surface of the bit line BL includes a laminate film of a magnetic layer 24a, for example, of nickel iron (NiFe) and a barrier metal layer 25a of tantalum (Ta), etc. In a silicon nitride film 22 interposed between the yoke cover YC and the bit line BL, a mixing layer 41 as a mixture of a metal material and an insulating material is formed by introducing, for example, tantalum (Ta) for a predetermined depth from the surface by a re-sputtering method. The mixing layer 41 has a function of enhancing the adhesion of the magnetic layer 24a of the yoke cover YC to the silicon nitride film 22. Since other configurations than described above are identical with those of the MRAM shown in FIG. 3 to FIG. 5, identical members carry same reference numerals for which duplicate description is not repeated.

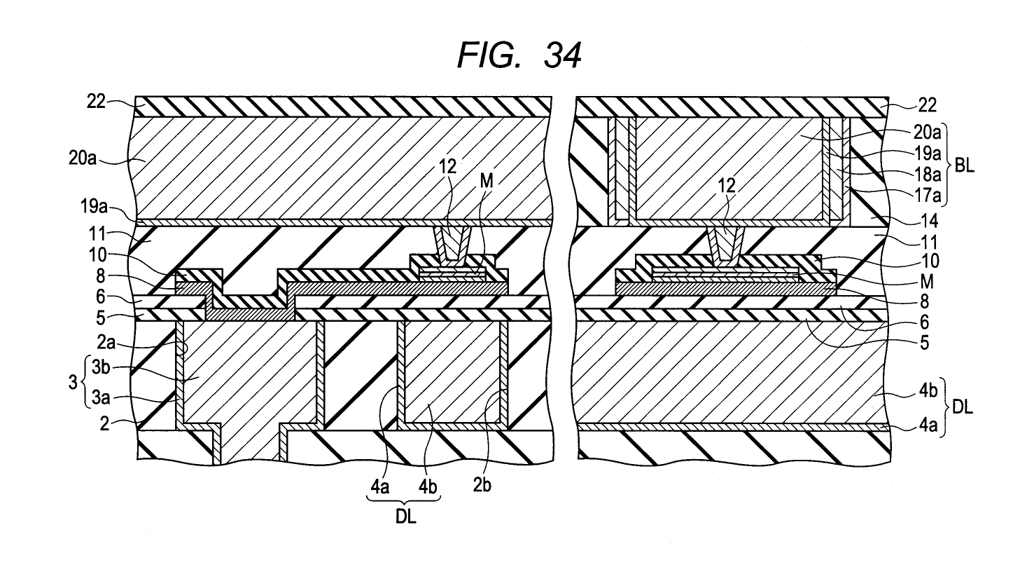

Then, a method of manufacturing the MRAM described above is to be described. At first, by way of the same steps as those shown in FIG. 6 to FIG. 13 described above, a silicon nitride film 22 as an antidiffusion film for the interconnect material is formed in contact with the upper surface of a bit line BL as shown in FIG. 34. Then, by applying sputtering to the silicon nitride film 22 in a predetermined sputtering chamber, a mixing layer formed by mixing a metal layer to the silicon nitride film as the insulating material is formed from the surface for a predetermined depth of the silicon nitride film 22.

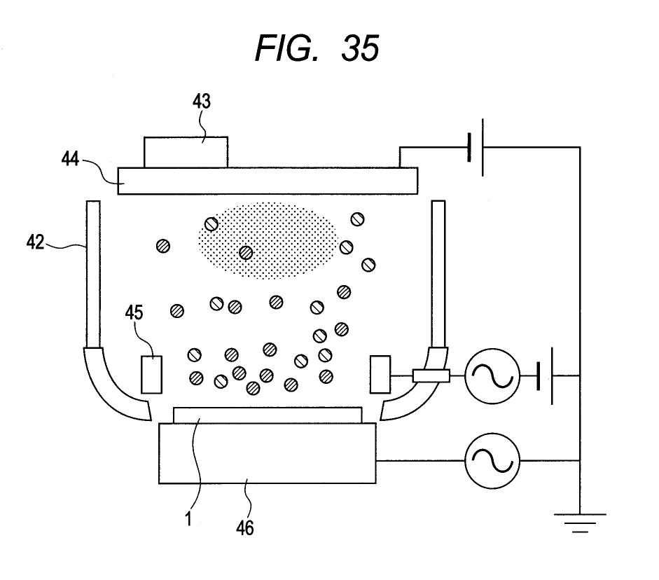

As shown in FIG. 35, a stage 46 is provided to a lower part inside of a sputtering chamber 42, and coils 45 are arranged so as to surround the stage 46. A target 44, for example, of nickel iron (NiFe) or tantalum (Ta) is arranged as the metal material above the stage 46. A magnet 43 is disposed above the target 44. An AC power source is coupled to the stage 46 and a high frequency power source and a direct current power source are coupled to the coil 45. Further, a direct current power source is coupled to the target 44.

A semiconductor substrate 1 (wafer) is placed on the stage 46, and a relatively high bias voltage is applied to the stage 46 while a relatively low bias voltage is applied to the target 44. An argon gas is introduced into the sputter chamber 42 to generate a plasma. When the plasma is generated, argon is attracted to the stage 46 at a relatively high bias voltage, and the silicon nitride film 22 on the surface of the wafer is sputtered by the attracted argon (sputter etching).

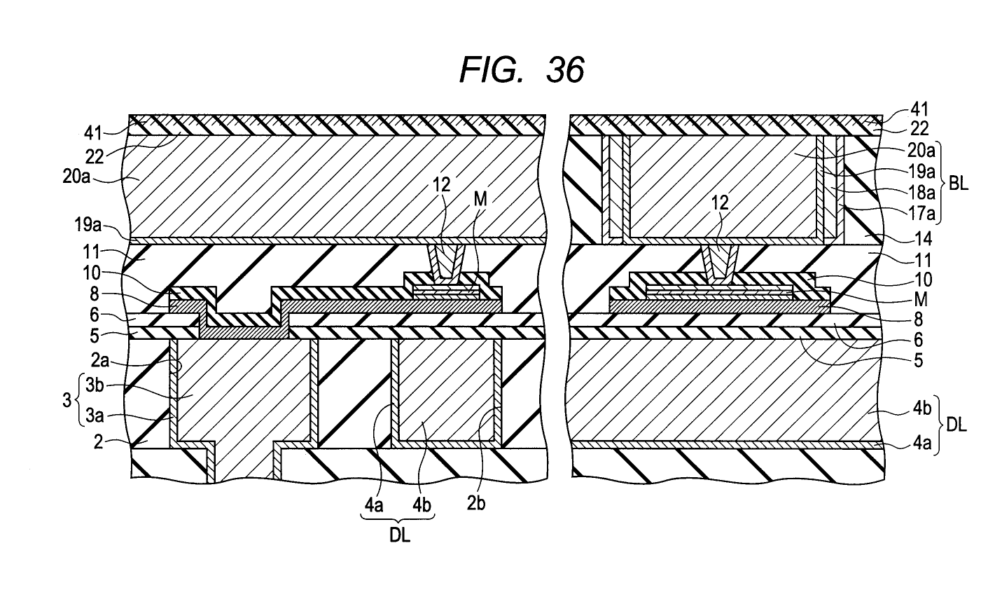

On the other hand, a portion of argon is also attracted toward the target 44 in which the relatively low bias voltage is applied to sputter nickel and iron (NiFe). Since the sputtered nickel iron (NiFe) is ionized, this is attracted toward the stage 46 at a relatively hither voltage, and nickel iron (NiFe) are implanted into the silicon nitride film 22. Thus, as shown in FIG. 36, nickel iron (NiFe) is introduced from the surface for a predetermined depth of the silicon nitride film 22 to form a mixing layer 41 in which nickel iron is mixed in the silicon nitride film 22.

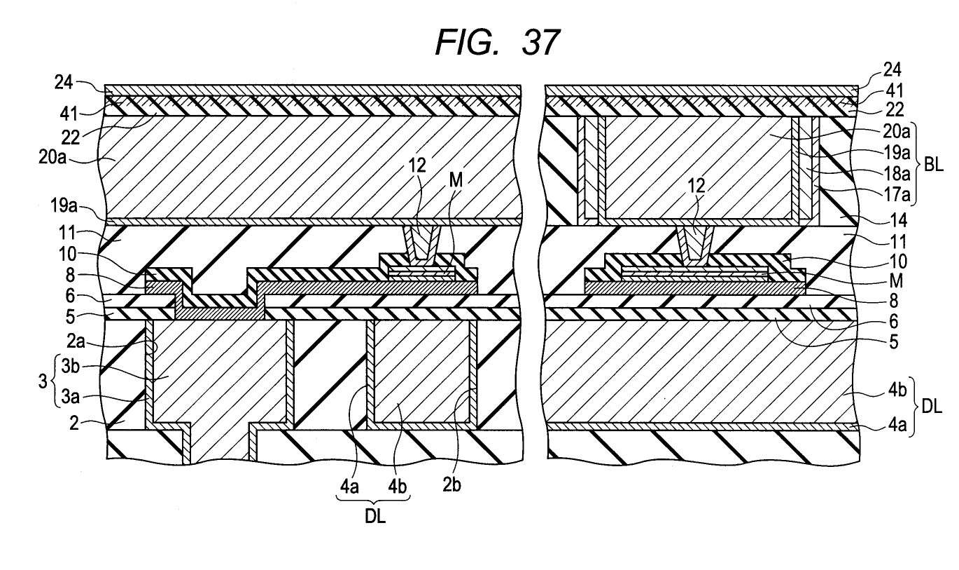

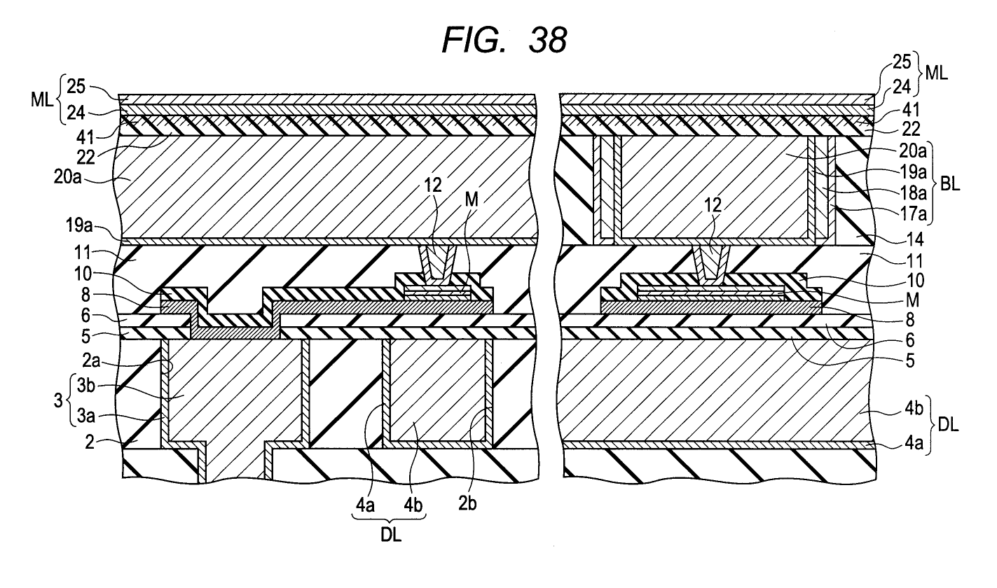

Then, the laminate films as the yoke cover are formed successively. At first, as shown in FIG. 37, a magnetic layer 24 having about 15 nm thickness of nickel iron (NiFe), etc. for shielding a magnetic field is formed in contact with the surface of the mixing layer 41 (silicon nitride film 22). Then, as shown in FIG. 38, a barrier metal layer 25 as an upper adhesion layer having about 15 nm thickness of tantalum (Ta), etc. is formed in contact with the surface of the magnetic layer 24. Thus a laminate film ML as the yoke cover is formed.

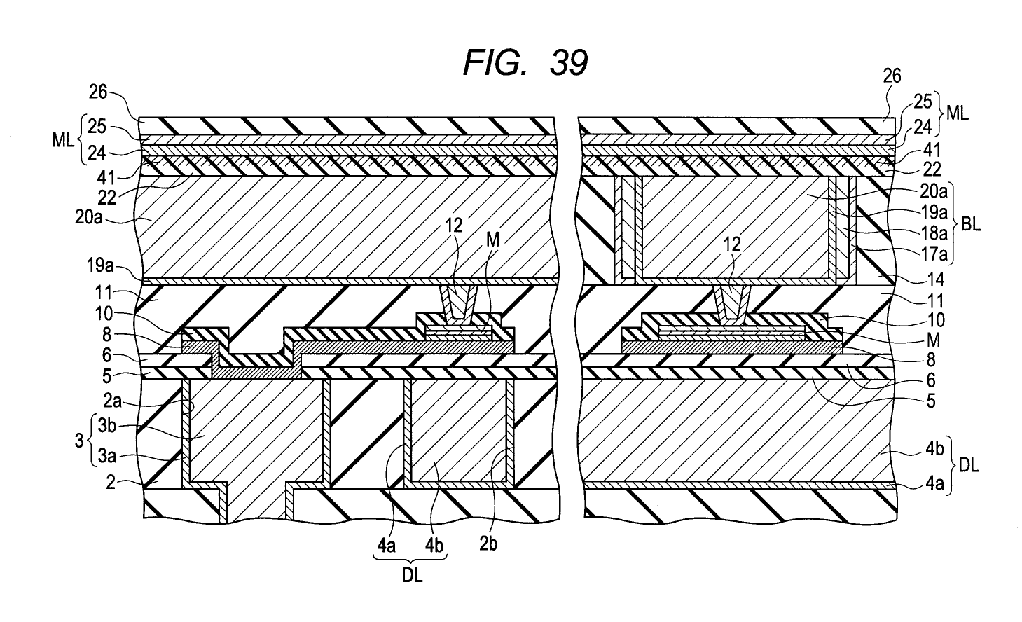

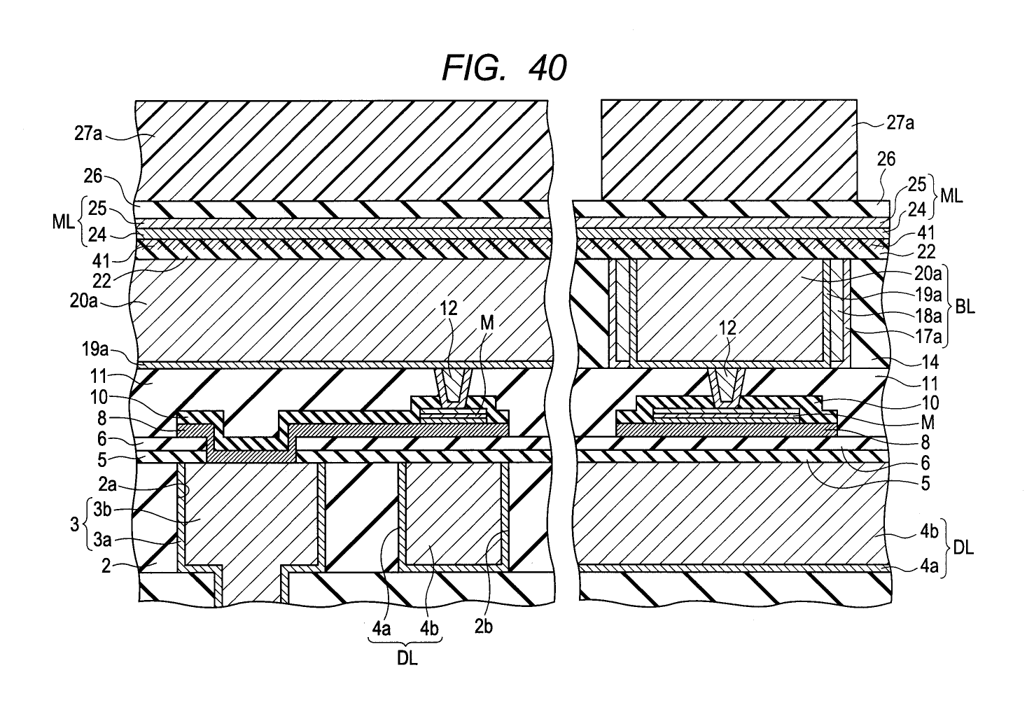

Then, photoengraving is applied for patterning the laminate film ML (24, 25). As shown in FIG. 39, an organic antireflection film 26 is formed on the surface of the barrier metal 25. Then, a photoresist (not illustrated) is coated on the surface of the antireflection film 26. Then, by applying photoengraving to the photoresist, a resist mask 27a for patterning the yoke cover is formed as shown in FIG. 40.

Then, the laminate film ML (24, 25) is patterned. At first, reactive ion etching is applied to the antireflection film 26 and the barrier metal layer 25 in an atmosphere of a gas mixture, for example, of a carbon tetrafluoride (CF₄) gas and an argon (Ar) gas by using the resist mask 27a as an etching mask thereby forming a mask (not illustrated) of the barrier metal layer 25 (step 1). Then, the resist mask 27a is removed and reactive ion etching is applied in an atmosphere of a gas mixture, for example, of carbon monoxide (CO), an ammonia (NH₃) gas, and an argon (Ar) gas by using a mask of the bather metal layer 25 as an etching mask (step 2) and, further, reactive ion etching is applied in an atmosphere of a gas mixture, for example, of a carbon tetrafluoride (CF₄) gas and an argon (Ar) gas (step 3), thereby patterning the magnetic layer 24.

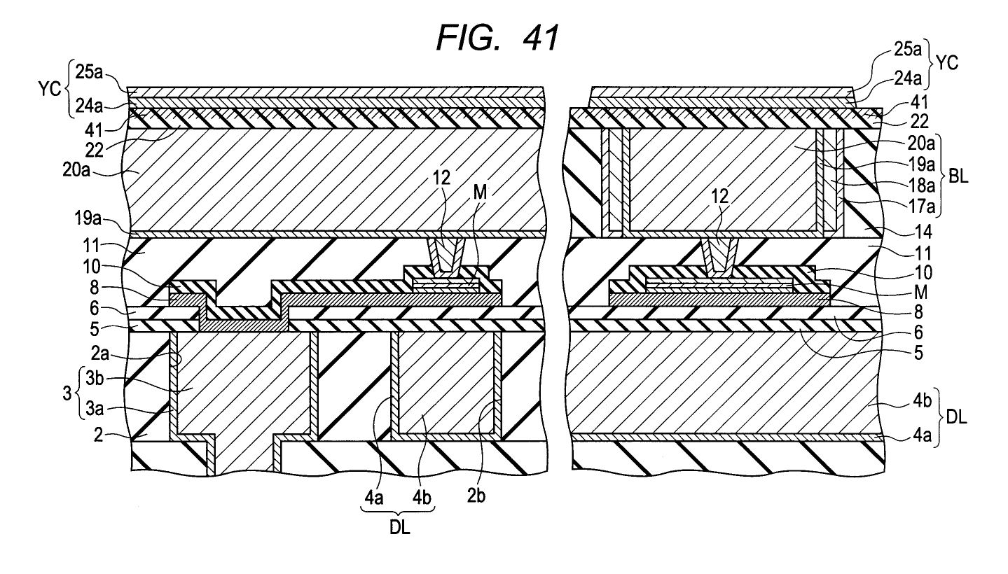

Thus, a yoke cover YC having a magnetic layer 24a and a barrier metal layer 25a is formed by patterning the laminate film ML (24, 25) as shown in FIG. 41. Successively, a main portion of MRAM is formed by forming a silicon nitride film 28 in contact with the surface of the yoke cover YC as shown in FIG. 32.

In the MRAM described above, the yoke cover YC has a laminate film of the magnetic layer 24a and the barrier metal 25a, in which the magnetic layer 24a is formed in contact with the surface of the silicon nitride film 22. Since nickel iron (NiFe) is a material which is generally excellent in corrosion resistance, less reactive, and stable, it is considered that adhesion with a material different from the magnetic body, particularly, an insulating film is poor. Accordingly, in a structure where the magnetic layer is formed directly to the insulating film, the magnetic layer tends to be peeled.

By performing various evaluations, the inventors have found that the adhesion between the yoke cover YC and the silicon nitride film 22 can be improved by applying re-sputtering to the surface of the silicon nitride film 22 as the insulating film before forming the magnetic layer as the yoke cover.

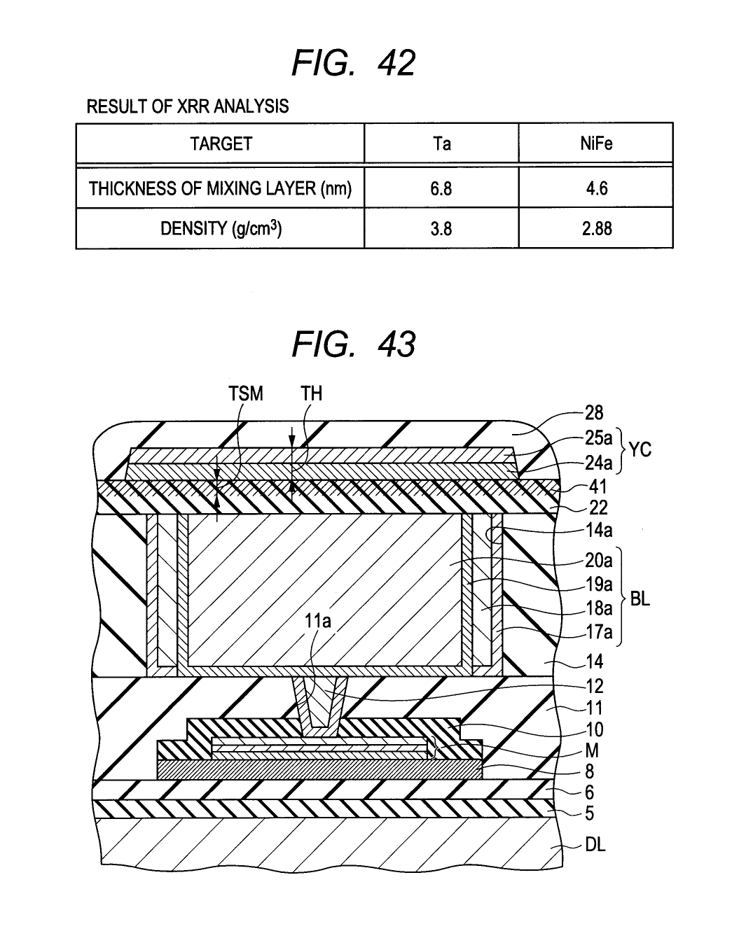

Evaluation for X-ray reflectivity (XRR) performed by the inventors is to be described. As a specimen, a wafer (semiconductor substrate) formed with a silicon oxide film of about 100 nm thickness was provided. Then, the wafer was placed on a stage in a sputtering chamber and re-sputtering was applied to the silicon oxide film for about 5 sec. As the material for the target, two kinds of materials, i.e., tantalum (Ta) and nickel iron (NiFe) were used. The result is shown in FIG. 42.

As shown in FIG. 42, when tantalum (Ta) was used as the material for the target, it has been found that tantalum (Ta) was implanted into the silicon oxide film from the surface for a depth of about 6.8 nm. On the other hand, when nickel iron (NiFe) was used as the material for the target, it has been found that nickel iron (NiFe) was implanted from the surface for a depth of about 4.6 nm in the silicon oxide film.

Further, the density of the silicon oxide film (average density for film thickness) of the silicon oxide film implanted with tantalum was 3.8 g/cm³ and the density of the silicon film (average density for film thickness) implanted with nickel iron was about 2.88 g/cm³, and it has been demonstrated that a region of different density from the that of the silicon oxide film was formed in the silicon oxide film applied with the re-sputtering. In the region, an insulating material forming the insulating film and a metal material such as implanted nickel iron (NiFe) were mixed and the inventors called the region as “mixing layer”.

The inventors considered that the mixing layer 41 was formed from the surface for a predetermined depth TSM in the silicon nitride film 22 in the MRAM described above as shown in FIG. 43 and the mixing layer 41 has a function as an adhesion layer for adhering the magnetic layer 24a of the yoke cover YC with the silicon nitride film 22. As the metal material for providing such a function as the adhesion layer, it is considered that those metals other than inactive metal (Au), etc. are preferred in addition to nickel iron (NiFe) or tantalum (Ta).

In the MRAM described above, the production cost can be suppressed while improving the throughput (by forming the same) by applying the reactive ion etching to the predetermined laminate film including the magnetic layer in the same manner as the MRAM shown in FIG. 3, etc. Further, the film thickness (magnetic layer+bather metal layer) TH of the yoke cover YC is preferably 10 nm or more and 50 nm or less in order to effectively confine the magnetic field (refer to FIG. 43).

Further, since the facet (lamination facet) of the yoke cover YC patterned by the reactive ion etching is in a forward tapered shape, overlap margin between the bit line BL and the yoke cover YC can be improved without lowering the exposure margin upon forming the resist mask and the leakage of the magnetic field can be suppressed and the magnetic field can be confined Further, the coverage of the silicon nitride film 28 as the antidiffusion film covering the yoke cover YC is also improved.

### Third Embodiment

An MRAM having a yoke cover including a relatively thick magnetic layer is to be described. In the MRAM shown in FIG. 3, etc., examples in which the thickness of the magnetic layer 24a in the laminate film of the yoke cover YC is about 15 nm have been described. Depending on the specification of MRAM, a magnetic layer having a thickness of about 25 nm or more is sometimes required.

In this case, when it is considered that the thickness of the upper barrier metal 25a is about identical with the thickness of the magnetic layer 24a, the upper limit for the thickness of the upper barrier metal layer 25a is 24 nm and the thickness of the upper bather metal layer 25a (maximum thickness: 24 nm) cannot be identical with the thickness of the magnetic layer 24a (25 nm or more) even when the thickness of the lower barrier metal layer 23a is defined as 1 nm.

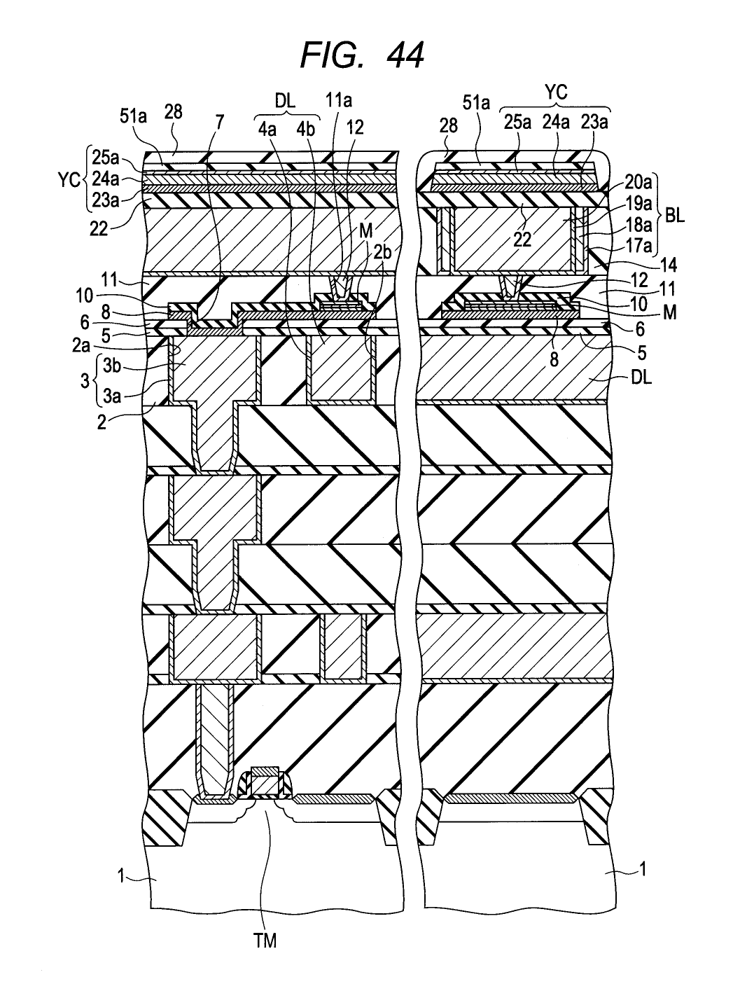

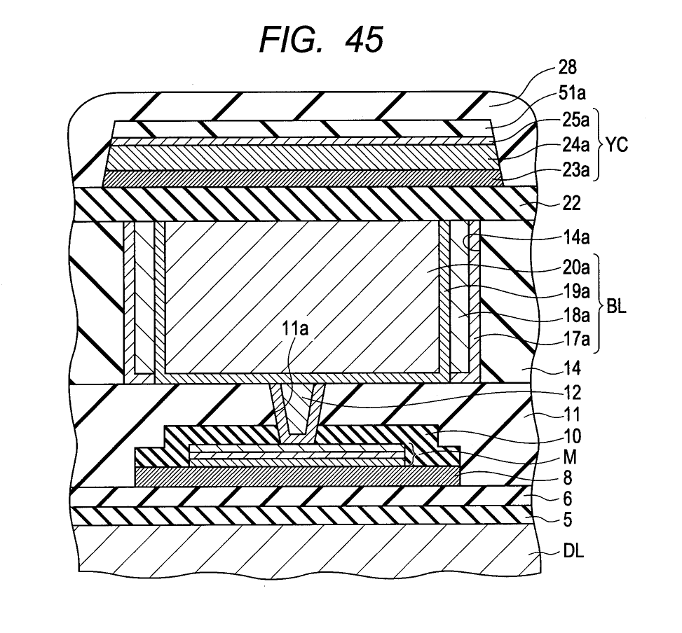

Assuming the case described above, a hard mask insulating film for compensating the thickness of the upper barrier metal layer is formed in the MRAM in this embodiment. As shown in FIG. 44 and FIG. 45, a silicon nitride film 51a as a hard mask which also serves as an antireflection film is formed in contact with the surface of the barrier metal layer 25a in the yoke cover YC. The sum of the thicknesses for the bather metal layer 25a and the silicon nitride film 51a is substantially identical with the thickness of the magnetic layer 24a. Since other configurations than those described above are identical with those in the MRAM shown in FIG. 3 to FIG. 5, identical members carry the same reference numerals for which duplicate descriptions are not repeated.

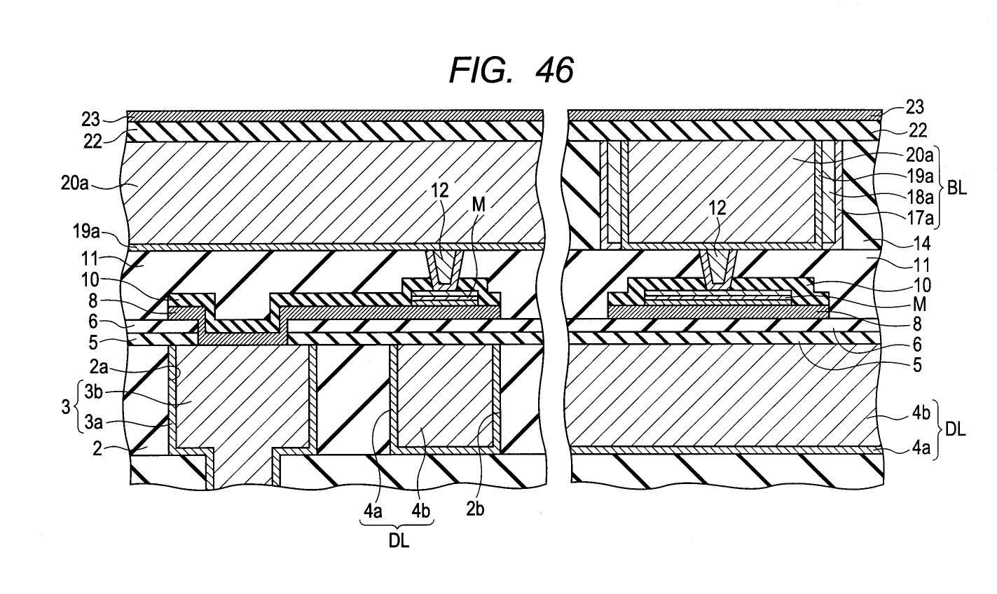

Then a method of manufacturing the MRAM is to be described. At first, after the same steps as those shown in FIG. 6 to FIG. 13 described above and as seen in FIG. 46, a silicon nitride film 22 as an antidiffusion film for the interconnect material is formed in contact with the upper surface of the bit line BL.

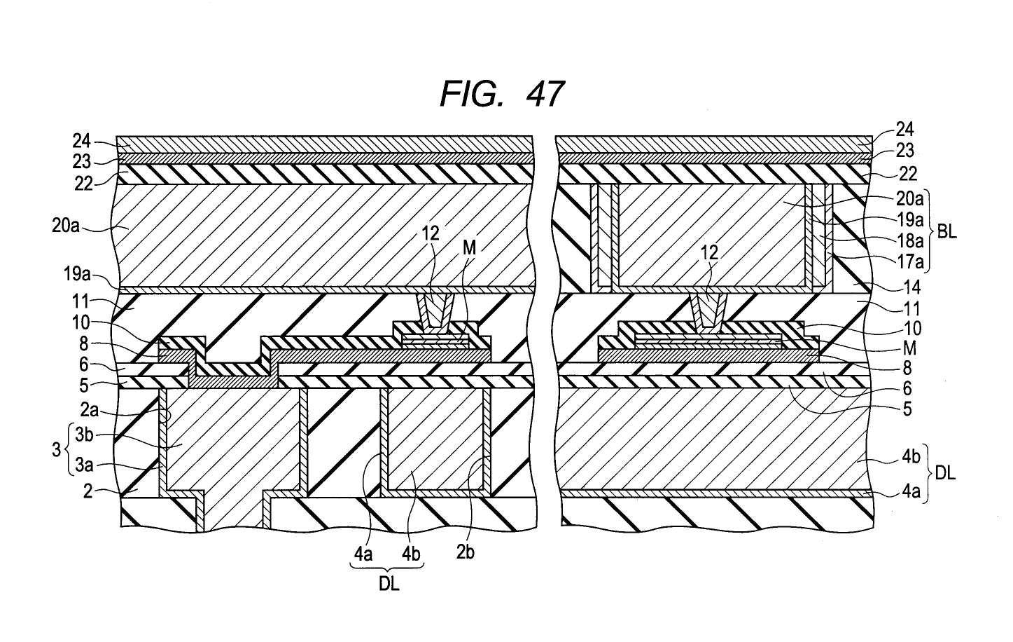

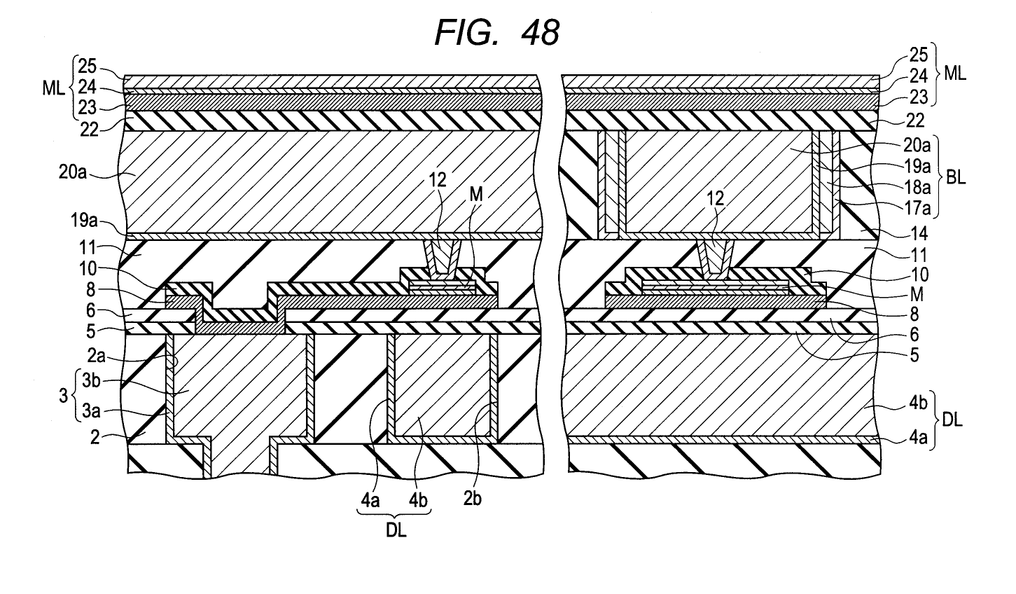

Then, laminate film as the yoke cover is formed successively. At first, a bather metal layer 23 as the lower adhesion layer of about 1 nm thickness, for example, of tantalum (Ta) is formed in contact with the surface of the silicon nitride film 22 by a sputtering method (See FIG. 46). Then, as shown in FIG. 47, a magnetic layer 24 having a thickness of about 25 nm, for example, of nickel iron (NiFe) for shielding a magnetic field is formed in contact with the surface of the barrier metal 23 by a sputtering method. Then, as shown in FIG. 48 a barrier metal layer 25 as an upper adhesion layer having a thickness of about 15 nm, for example, of tantalum (Ta) is formed in contact with the surface of the magnetic layer 24 by a sputtering method. Thus, a laminate film ML as a yoke cover is formed.

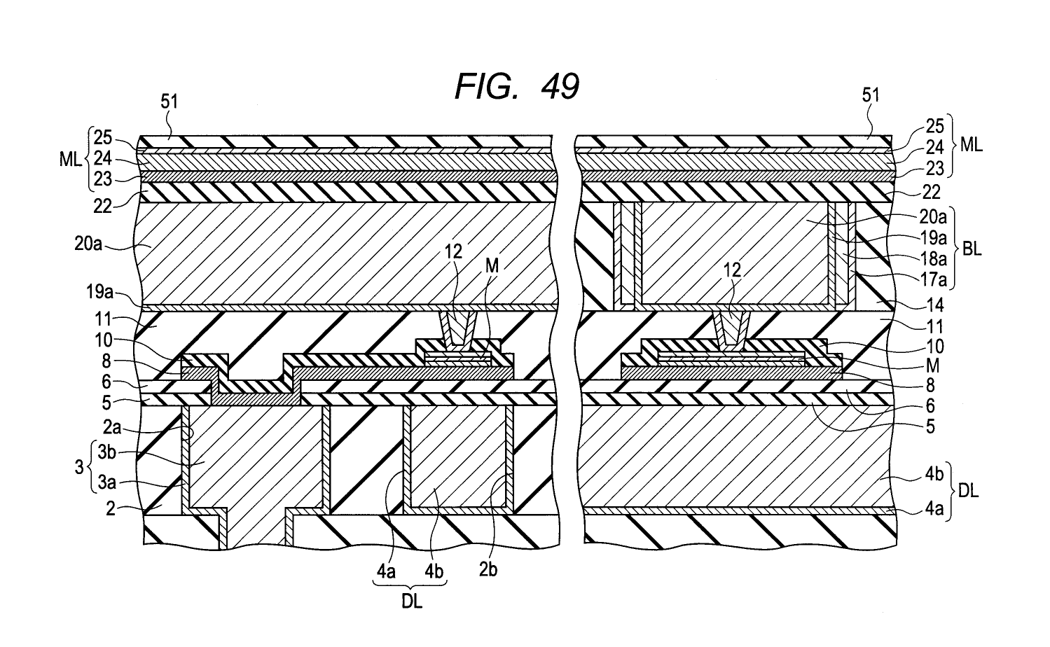

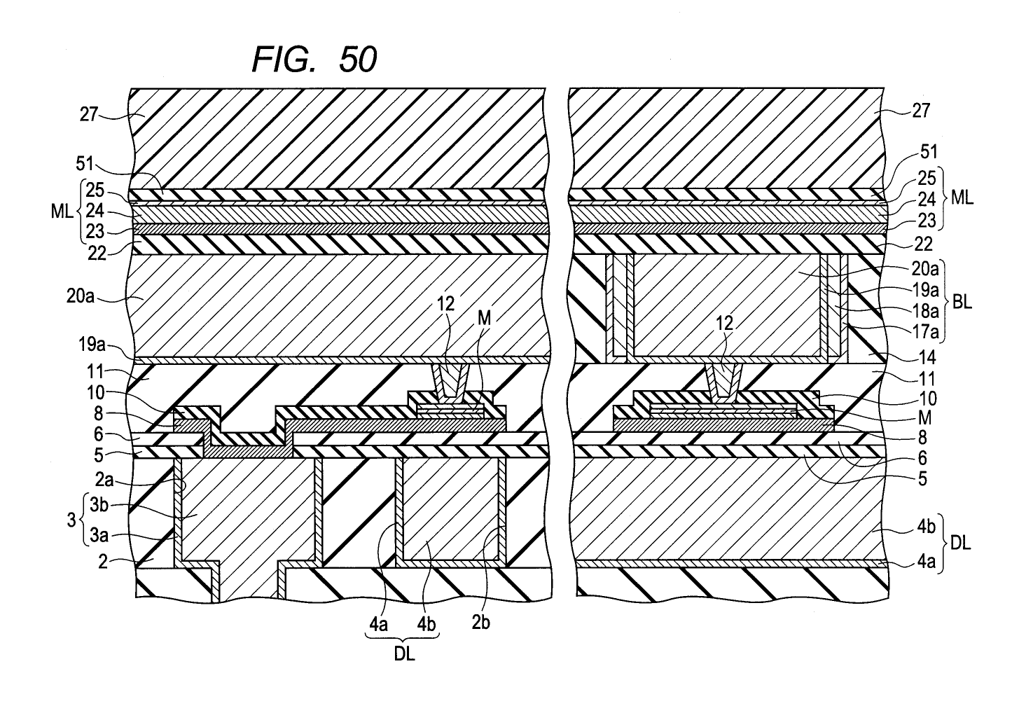

Then, as shown in FIG. 49, a silicon nitride film 51 as a hard mask which also serves as an antireflection film is formed in contact with the surface of the barrier metal layer 25. The thickness of the silicon nitride film 51 is such that the sum of the film thicknesses for the silicon nitride film 51 and the bather metal layer 25 is about identical with the thickness of the magnetic layer 24.

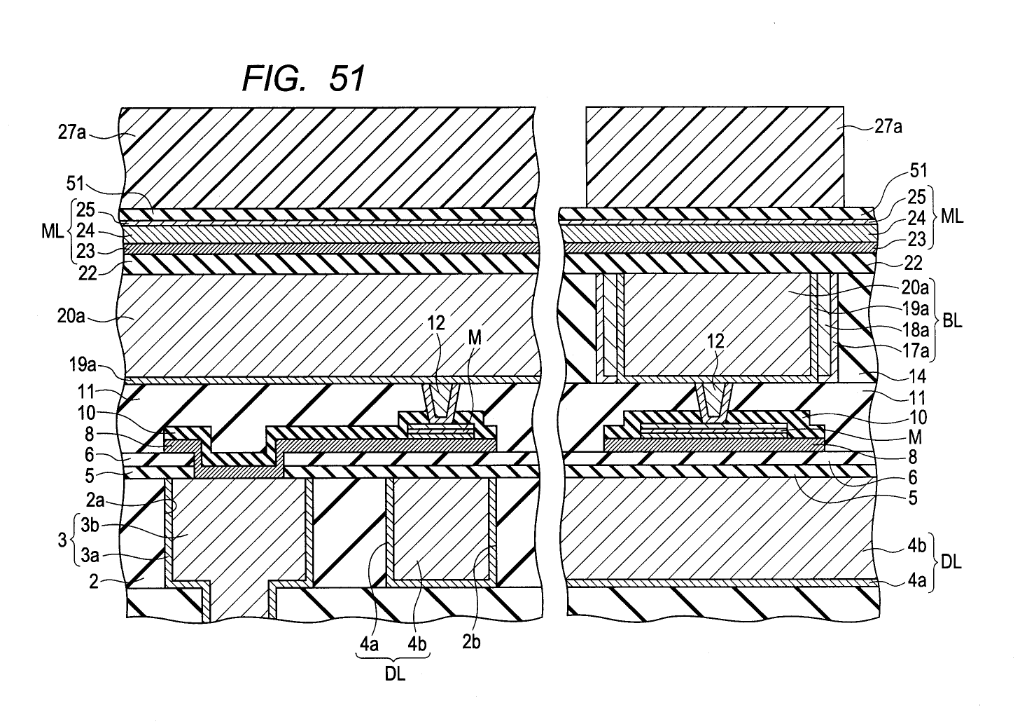

Then, photoengraving is applied for patterning the laminate film ML (23, 24, 25). At first, as shown in FIG. 50, a photoresist 27 is coated on the surface of the silicon nitride film 51 as the antireflection film. Then, a resist mask 27a for patterning the yoke cover is formed by applying photoengraving to the photoresist 27 as shown in FIG. 51.

Then, the laminate film ML (23, 24, 25) is patterned. At first, reactive ion etching is applied to the silicon nitride film 51 and the barrier metal layer 25 in an atmosphere of a gas mixture, for example, of a carbon tetrafluoride (CF₄) gas and an argon (Ar) gas by using the resist mask 27a as an etching mask, thereby forming the mask of the silicon nitride film 51 and the barrier metal layer 25 (not illustrated) (step 1). Then, the result mask 27a is removed and reactive ion etching is applied to the magnetic layer 24 in an atmosphere of a gas mixture, for example, of carbon monoxide (CO), an ammonia (NH₃) gas, and an argon (Ar) gas using the mask of the antireflection film 26 and the barrier metal layer 25 as an etching mask, thereby patterning the magnetic layer 24 (step 2). Then, reactive ion etching is applied to the bather metal layer 23 in an atmosphere of a gas mixture, for example, of a carbon tetrafluoride (CFO gas and an argon (Ar) gas by using the mask of the bather metal layer 25 as an etching mask, thereby pattering the barrier metal layer 23 (step 3).

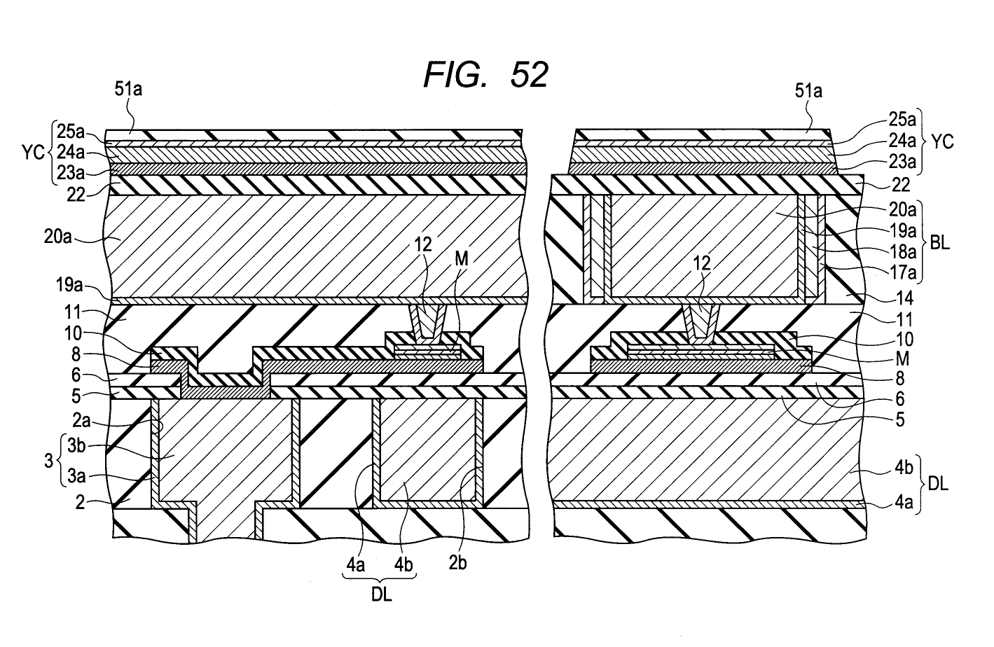

Thus, by patterning the laminate film ML (23, 24, 25) by the reactive ion etching, a yoke cover YC having the barrier metal layer 23a, the magnetic layer 24a and the barrier metal 25a is formed as shown in FIG. 52. The silicon nitride film 51a as the hard mask is left on the surface of the barrier metal layer 25a of the yoke cover YC. Subsequently, a main portion of the MRAM is formed, as shown in FIG. 45, by forming a silicon nitride film 28 in contact with the lamination facet of the yoke cover YC and the surface of the silicon nitride film 51a.

The MRAM described above can provide the following advantageous effects. At first, in MRAM, the magnetic layer 24a of the yoke cover YC is sometimes required to have a relatively thick thickness of about 25 nm or more in order not to leak a magnetic field to the outside depending on the specification of the MRAM. On the other hand, there is an upper limit for the thickness TH of the yoke cover YC (about 50 nm) with a view point of suppressing the displacement of alignment as has been described above. Further, the upper barrier metal layer 25 is required to have a thickness about identical to that of the magnetic layer 24 for ensuring the function as an etching mask upon applying the reactive ion etching.

In some cases, the thickness of the barrier metal layer 25 cannot be increased to such an extent that it is identical with that of the magnetic layer 24 due to the restriction of the upper limit for the thickness of the yoke cover YC, and sufficient thickness cannot be ensured only by the barrier metal layer 25. In the MRAM described above, the thickness as the hard mask can be ensured by forming the silicon nitride film 51 having a thickness for compensating the insufficiency as the hard mask can be formed on the surface of the barrier metal layer 25, thereby capable of patterning the yoke cover YC reliably.

Further, since the silicon nitride film 51 is transparent, the silicon nitride film 51 results in no troubles in the alignment. Further, since the silicon nitride film 51 has the function as the antireflection film, a step of forming an organic antireflection film can be saved.

Further, since the upper barrier metal layer 25 is covered with the silicon nitride film 51, this can prevent oxidation of the barrier metal layer and change of the stress upon applying the reactive ion etching. Accordingly, the lower barrier metal layer 23a for ensuring the adhesion between the yoke cover YC and the silicon nitride film 22 can also be saved.

In the case of saving the lower barrier metal layer, when the silicon nitride film is intended to be formed by using an oxygen-containing gas, the upper barrier metal layer 25 may be oxidized to cause change of stress, and peeling may be caused sometimes at the boundary between the silicon nitride film 22 and the magnetic layer 24. Therefore, in a case of saving the lower barrier metal layer 23a, it is an essential condition to form the silicon nitride film 51 in an oxygen-free atmosphere in order to avoid such peeling. Accordingly, the silicon nitride film 51 is preferably formed by reacting monosilane (SiH₄) and an ammonia (NH₃) gas.

Further, in the MRAM described above, the production cost can be suppressed while improving the throughput (by forming the MRAM) by applying the reactive ion etching to a predetermined laminate film containing the magnetic layer in the same manner as the MRAM shown in FIG. 3, etc. Further, the thickness (barrier metal layer 23a+magnetic layer 24a+barrier metal layer 25a) TH of the yoke cover YC is preferably 10 nm or more and 50 nm or less for suppressing the displacement of alignment upon forming the resist mask and effectively confining the magnetic field.

Further, since the facet (lamination facet) of the yoke cover patterned by the reactive ion etching is in the forward tapered shape, the overlap margin between the bit line BL and the yoke cover YC can be enhanced without lowering the exposure margin upon forming the resist mask, and the leakage of the magnetic field can be suppressed and the magnetic field can be confined. Further, the coverage of the silicon nitride film 28 as the antidiffusion film covering the yoke cover YC is also improved.

### Fourth Embodiment

In each of the MRAMs described above, examples in which the silicon nitride film as the antidiffusion film is formed between the yoke cover YC and the bit line BL for preventing the material of the bit line BL from diffusing have been described. In this embodiment, an MRAM in which the antidiffusion film is not interposed between the yoke cover YC and the bit line BL is to be described.

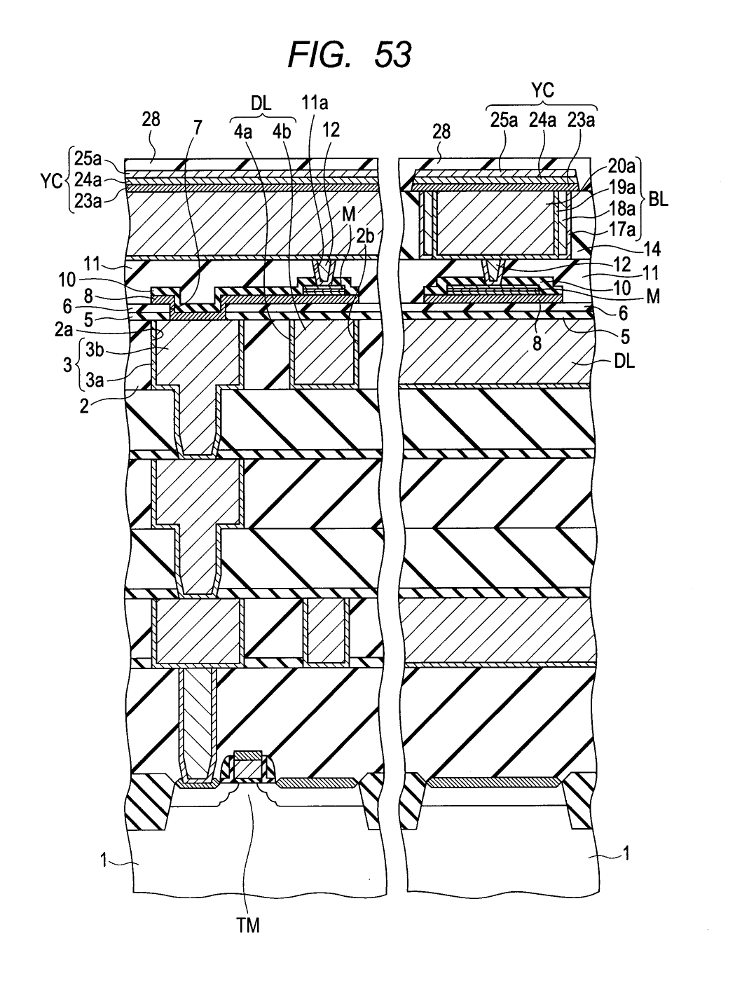

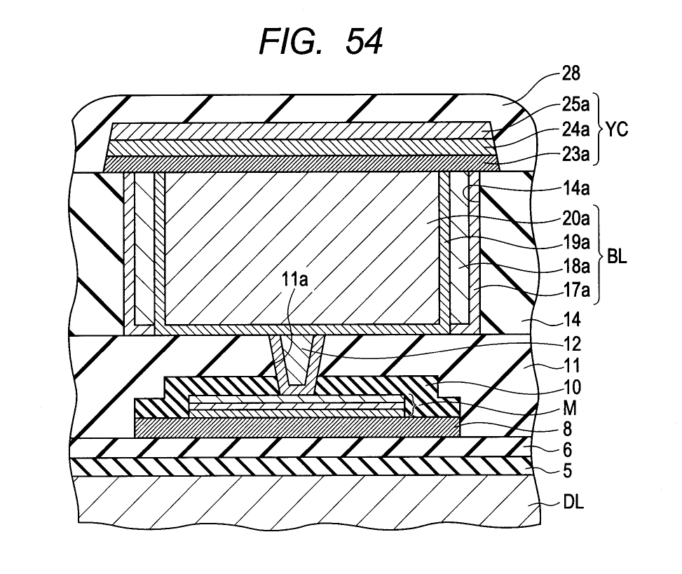

As shown in FIG. 53 and FIG. 54, the lower barrier metal layer 23a of the yoke cover YC is formed in contact with the upper surface of the bit line BL. Since other configurations are identical with those of the MRAMs shown in FIG. 3 to FIG. 5, identical members carry the same reference numerals for which duplicate descriptions are not repeated.

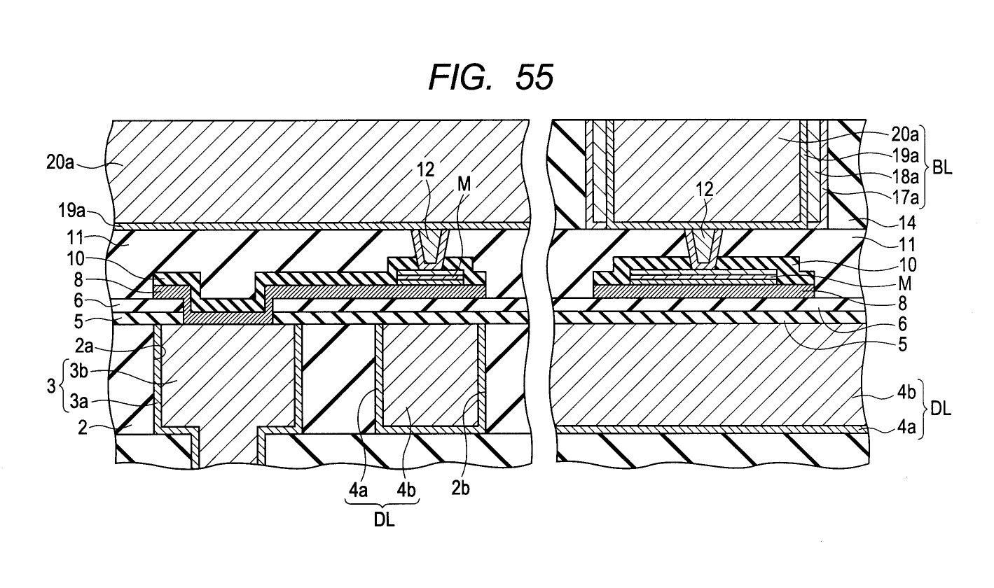

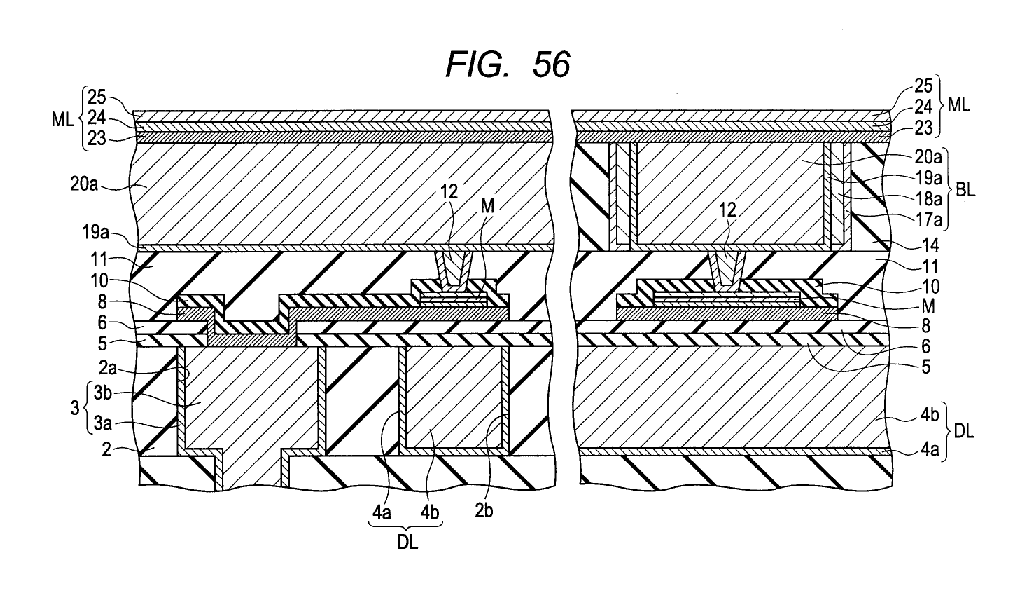

Then, a method of manufacturing the MRAM is to be described. At first, after identical steps with those shown in FIG. 6 to FIG. 12 described above, a bit line BL is formed as shown in FIG. 55. Then, laminate film as the yoke cover is formed successively. At first, as shown in FIG. 56, a barrier metal layer 23 having a thickness of about 1 nm as the lower adhesion layer of tantalum (Ta), etc. is formed in contact with the upper surface of the bit line BL by sputtering method.

Then, a magnetic layer 24, for example, of nickel iron (NiFe) for shielding a magnetic field is formed in contact with the surface of the bather metal 23 by a sputtering method. Then, a bather metal 25 as an upper adhesion layer, for example, of tantalum (Ta) is formed in contact with the surface of the magnetic layer 24 by a sputtering method. Thus, a laminate film ML as the yoke cover is formed.

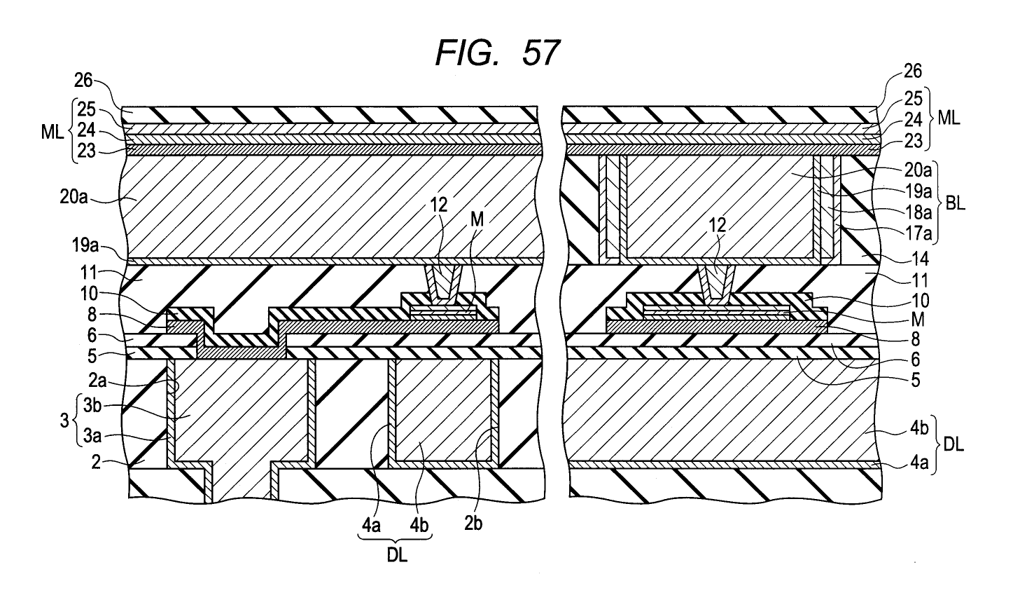

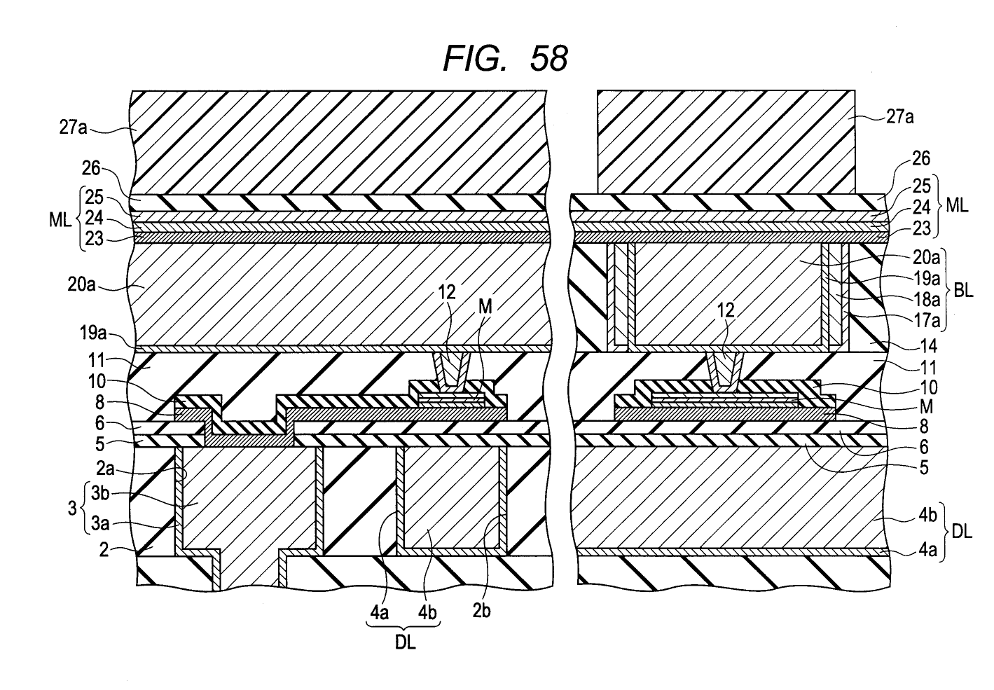

Then, photoengraving is applied for patterning the laminate film ML (23, 24, 25). At first, as shown in FIG. 57, an organic antireflection film 26 is formed in contact with the surface of the barrier metal 25. Then, a photoresist (not illustrated) is coated on the surface of the antireflection film 26. Then, a resist mask 27a for patterning the yoke cover is formed by applying photoengraving to the photoresist as shown in FIG. 58.

Then, the laminate film ML (23, 24, 25) is patterned. At first, reactive ion etching is applied to the antireflection film 26 and the barrier metal layer 25 in an atmosphere of a gas mixture, for example, of a carbon tetrafluoride (CF₄) gas and an argon (Ar) gas using the resist mask 27a as an etching mask thereby forming a mask (not illustrated) of the barrier metal layer 25. (step 1). Then, the resist mask 27a is removed and reactive ion etching is applied to the magnetic layer 24 in an atmosphere of a gas mixture, for example, of a carbon monoxide (CO) gas, an ammonia (NH₃) gas, and an argon (Ar) gas by using the mask of the bather metal layer 25 as an etching mask, thereby patterning the magnetic layer 24 (step 2). Then, reactive ion etching is applied to the bather metal layer 23 in an atmosphere of a gas mixture, for example, of a carbon tetrafluoride (CF₄) gas and an argon (Ar) gas by using the mask of the barrier metal layer 25 as an etching mask, thereby patterning the barrier metal layer 23 (step 3).

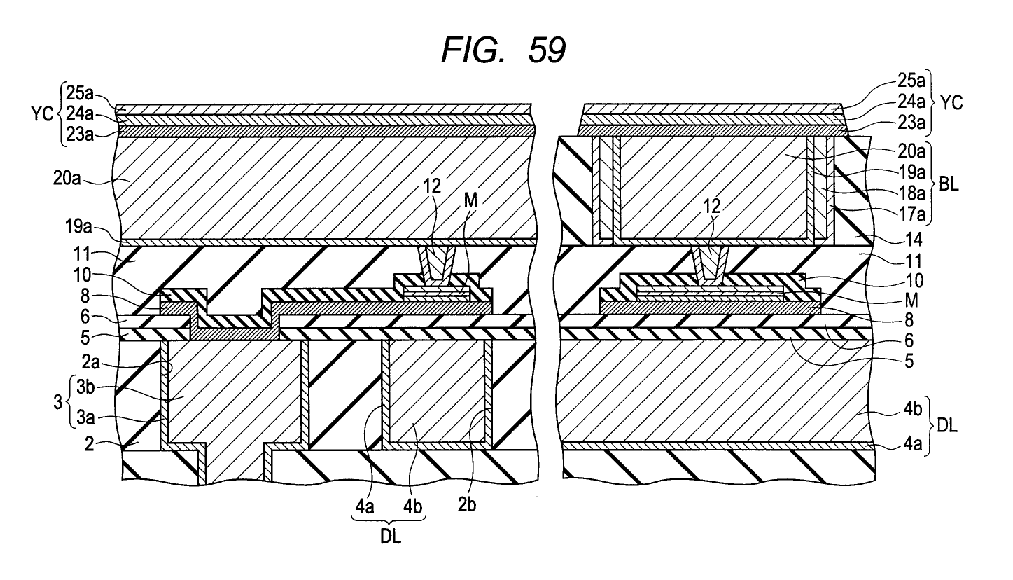

Thus, a yoke cover YC including the barrier metal layer 23a, a magnetic layer 24a, and a barrier metal layer 25a is formed by patterning the laminate film ML (23, 24, 25) as shown in FIG. 59. Subsequently, a main portion of the MRAM is formed as shown in FIG. 54 by forming a silicon nitride film 28 in contact with the surface of the yoke cover YC.

In the MRAM described above, the yoke cover YC is formed so as to cover the bit line BL in a manner in contact with the surface of the bit line BL. By performing various evaluations, the present inventors have found that diffusion of the interconnect material of the bit line BL can be prevented by the bather metal layer 23a when the thickness of the barrier metal 23a of the yoke cover YC is about 1 nm or more. Eliminating of the silicon nitride film as the antidiffusion film can contribute to the reduction of the production cost.

In the MRAM described above, the production cost can be suppressed while improving the throughput (by forming the MRAM) by applying the reactive ion etching to the predetermined laminate film including the magnetic layer in the same manner as in the MRAMs shown in FIG. 3, etc. Further, for suppressing the displacement in the alignment upon forming the resist mask and effectively confining the magnetic field, the thickness (bather metal 23a+magnetic layer 24a+barrier metal layer 25a) TH of the yoke cover YC is preferably 10 nm or more and 50 nm or less.

Further, since the facet (lamination facet) of the yoke cover patterned by the reactive ion etching is in the forward tapered shape, overlap margin between the bit line BL and the yoke cover YC can be improved without lowering the exposure margin upon forming the resist mask and the leakage of the magnetic field can be suppressed and the magnetic field can be confined. Further, coverage of the silicon nitride film 28 as the antidiffusion film covering the yoke cover YC is also improved.

The semiconductor device (MRAM) according to each of the embodiments has a feature in that the yoke cover YC is patterned by applying the three steps of reactive ion etching to the predetermined laminate film. While the gas mixture of the carbon tetrafluoride (CF₄) gas and the argon (Ar) gas is described as an example of gas species in the first step, the gas species are not restricted thereto, but they may be a gas mixture of a halogen-based gas and an argon gas.

Further, while a gas mixture of carbon monoxide, an ammonia (NH₃) gas, and an argon (Ar) gas is described as an example of gas species in the second step, the gas species are not restricted thereto, but they may be a gas mixture, for example, of a trifluoromethane (CHF₃) gas, an ammonia (NH₃) gas, and oxygen (O₂), or a gas mixture of a chlorine (Cl₂) gas and an argon (Ar) gas.

Further, as gas species in the third step, a gas mixture including the carbon tetrafluoride (CF₄) gas and the argon (Ar) gas is described as an example. However, the gas species are not restricted thereto but, for example, a gas mixture comprising a gas containing carbon as an element and an argon (Ar) gas such as a gas mixture of a CₓF_{y} (x=1 to 6, y=1 to 8 (excluding x=1, y=4)) gas and an argon (Ar) gas, a gas mixture of a trifluoromethane (CHF₃) gas and an argon (Ar) gas, a gas mixture of a difluoromethane (CH₂F₂) gas and an argon (Ar) gas, and a gas mixture of carbon monoxide (CO) and an argon gas (Ar) can also be used. Further, also a gas mixture of ammonia (NH₃) and an argon gas (Ar) can also be used for the etching at the third step.

While the silicon nitride film has been described as an example of the film for preventing diffusion of the interconnect material of the bit line, any insulating film having an antidiffusion effect may be used and, for example, a silicon carbonitride (SiCN) film or a silicon oxynitride (SiON) film, etc. can also be used. While the tantalum (Ta) film has been described as an example of the lower adhesion layer, any material showing adhesion to both of the lower insulating film and the upper magnetic film may be used and, for example, a tantalum nitride (TaN) film, a titanium (Ti) film, a titanium nitride (TiN) film, a nickel (Ni) film, an iron (Fe) film, a tungsten (W) film, etc. can also be used. While the tantalum (Ta) film has been described as an example of the upper adhesion layer, any film applicable as the hard mask may be used and, for example, a tantalum nitride (TaN) film, a titanium nitride (TiN) film, or a titanium (Ti) film can also be used.

While the silicon nitride film has been described as an example of the antireflection film, BARC (Bottom Antireflective Coating), a silicon oxynitride (SiON) film, etc. can be used. While nickel iron (NiFe) has been described as an example of the magnetic layer, any iron (Fe) containing magnetic alloy may be used and, for example, cobalt iron (CoFe), etc. may also be used. While a copper interconnect formed by a damascene method has been described as an example of the bit line, an aluminum (Al) interconnect may also be used.

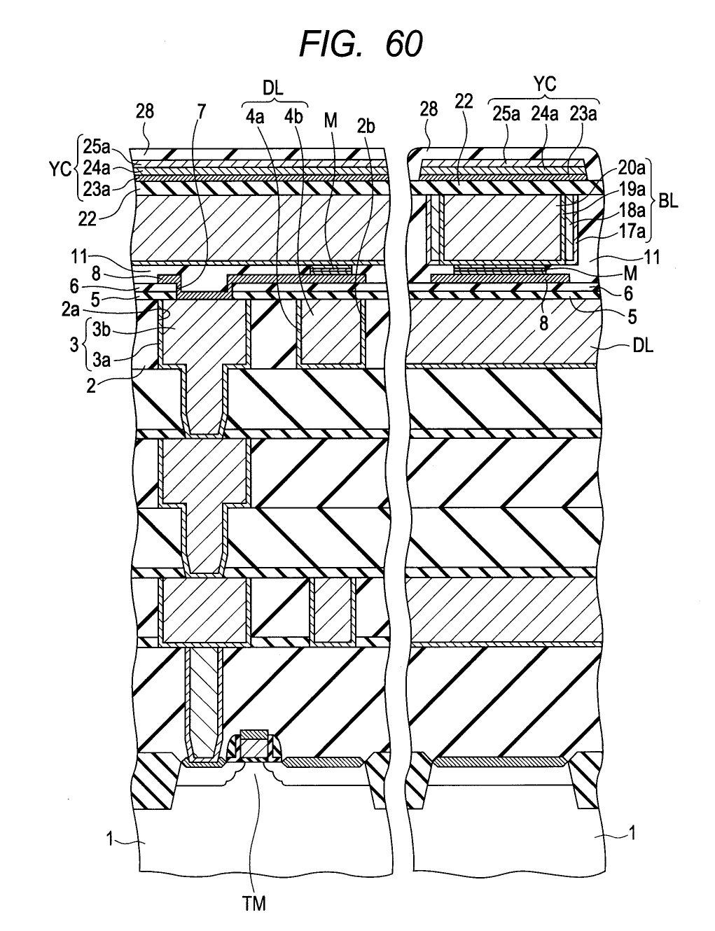

Further, in each of the MRAMs described above as shown in FIG. 3, etc., while the structure in which the magnetoresistive element M and the bit line BL are electrically coupled by way of the top via 12 has been described as the example, the yoke cover YC described above can be applied also to an MRAM in which a bit line BL is coupled directly to a magnetoresistive element M without providing the top via as shown in FIG. 60. In FIG. 60, members identical with those in the structure shown in FIG. 3 carry the same reference numerals.

Embodiments disclosed in the present application are examples and the invention is not restricted to them. Instead, the invention is defined by the scope of the claims presented below.

The present invention is utilized effectively to MRAMs having magnetoresistive elements as a memory device.

What is claimed is:

1. A method of manufacturing a semiconductor device comprising the steps of:
forming a magnetoresistive element over a main surface of a semiconductor substrate;
forming a bit line extending in a predetermined direction just above the magnetoresistive element at a distance, the bit line having an upper surface;
forming a laminate film so as to cover the bit line; and
forming a yoke cover for shielding a magnetic field generated by a current flowing through the bit line by applying fabrication to the laminate film,
wherein the step of forming the laminate film includes the steps of
forming a first adhesion layer so as to cover the bit line, the first adhesion layer having an upper surface;
forming a magnetic layer in contact with the upper surface of the first adhesion layer, the magnetic layer having an upper surface; and
forming a second adhesion layer in contact with the upper surface of the magnetic layer, the second adhesion layer having an upper surface, and
wherein the step of forming the yoke cover includes:
a step of forming a resist mask so as to cover a region above the bit line;
a first step of patterning the second adhesion layer by applying reactive ion etching with a halogen-based gas using the resist mask as an etching mask;
a second step of applying reactive ion etching with ammonia and argon-based gas by using the patterned second adhesion layer as an etching mask; and
a third step of applying reactive ion etching with a gas containing carbon as an element by using the patterned second adhesion layer as an etching mask.

2. The method of manufacturing a semiconductor device according to claim 1, comprising a step of:
before the step of forming the laminate film, forming an antidiffusion film in contact with the upper surface of the bit line, the antidiffusion film for preventing diffusion of an interconnect material of the bit line; and
wherein in the step of forming the laminate film, the first adhesion layer is formed in contact with an upper surface of the antidiffusion film.

3. The method of manufacturing a semiconductor device according to claim 2, comprising a step of:
after the step of forming the laminate film, forming an insulating film in contact with the upper surface of the second adhesion layer,
wherein the insulating film and the second adhesion layer are patterned in the first step in the step of forming the yoke cover, and
wherein the patterned insulating film and second adhesion layer are used as etching masks in the second step and the third step respectively, in the step of forming the yoke cover.

4. The method of manufacturing a semiconductor device according to claim 1,
wherein the first adhesion layer is formed in contact with the upper surface of the bit line in the step of forming the laminate film.

5. A method of manufacturing a semiconductor device comprising the steps of:
forming a magnetoresistive element over a main surface of a semiconductor substrate;
forming a bit line extending in a predetermined direction just above the magnetoresistive element at a distance, the bit line having an upper surface;
forming an antidiffusion film in contact with the upper surface of the bit line, the antidiffusion film for preventing diffusion of an interconnect material of the bit line;
forming a laminate film in contact with an upper surface of the antidiffusion film; and
forming a yoke cover for shielding a magnetic field generated by a current flowing through the bit line by applying fabrication to the laminate film, and further including a step of:
introducing, between the step of forming the antidiffusion film and the step of forming the laminate film, a metal material to the antidiffusion film thereby forming a mixing layer containing the metal material, the mixing layer extending from an upper surface of the antidiffusion film to a predetermined depth of the antidiffusion film,
wherein the step of forming the laminate film includes the steps of:
forming a magnetic layer in contact with an upper surface of the antidiffusion film, and
forming an adhesion layer in contact with the surface of the magnetic layer, and
wherein the step of forming the yoke cover includes:
a step of forming a resist mask so as to cover a region arranged just above the bit line over the surface of the adhesion layer;
a first step of patterning the adhesion layer by applying reactive ion etching with a halogen-based gas using the resist mask as an etching mask;
a second step of applying reactive ion etching with ammonia and an argon-based gas using the patterned adhesion layer as an etching mask; and
a third step of applying reactive ion etching with a gas containing carbon as an element by using the patterned adhesion layer as an etching mask.

6. The method of manufacturing a semiconductor device according to claim 5, wherein the metal material is introduced by a re-sputtering method in the step of forming the mixing layer.

7. A semiconductor device comprising:
a magnetoresistive element formed over a main surface of a semiconductor substrate;
a bit line having an upper surface and extending in a predetermined direction just above the magnetoresistive element at a distance; and
a yoke cover covering the upper surface of the bit line and capable of shielding a magnetic field generated by a current flowing through the bit line,
wherein the yoke cover has a laminate film having a lamination facet with a forward tapered shape, and
wherein the laminate film includes:
a magnetic layer having an upper surface and a lower surface; and
an upper adhesion layer in contact with the upper surface of the magnetic layer.

8. The semiconductor device according to claim 7,
wherein the laminate film further includes a lower adhesion layer in contact with the lower surface of the magnetic layer.

9. The semiconductor device according to claim 8, including:
an antidiffusion film in contact with a lower surface of the lower adhesion layer and also in contact with the upper surface of the bit line for preventing diffusion of interconnect material of the bit line into the yoke cover.

10. The semiconductor device according to claim 9, including:
an insulating film in contact with an upper surface of the upper adhesion layer,
wherein a facet of the insulating film has a forward tapered shape contiguous with the forward tapered shape of the lamination facet.

11. The semiconductor device according to claim 8,
wherein the lower adhesion layer is in contact with the upper surface of the bit line.

12. The semiconductor device according to claim 7, including:
an antidiffusion film in contact with the lower surface of the magnetic layer and also in contact with the upper surface of the bit line for preventing diffusion of interconnect material of the bit line into the yoke cover,
wherein the antidiffusion film has a mixing layer containing a metal material for adhesion with the yoke cover, the mixing layer extending from an upper surface of the antidiffusion film to a predetermined depth of the antidiffusion film.

13. The semiconductor device according to claim 7,
wherein a thickness of the yoke cover is 10 nm or more and 50 nm or less.

14. The semiconductor device according to claim 7,
wherein a cap layer is formed in contact with an upper surface of the yoke cover.

15. A semiconductor device comprising:
a magnetoresistive element positioned between a digit line extending in a first direction below the magnetoresistive element and a bit line extending in a second direction above the magnetoresistive element, the bit line having an upper surface;
a layer in contact with the bit line; and
a yoke cover positioned over the bit line and configured to shield a magnetic field generated by a current flowing in the bit line, the yoke cover comprising at least:
a magnetic layer having an upper surface; and
an upper adhesion layer in contact with the upper surface of the magnetic layer, with the magnetic layer being closer to the bit line than the upper adhesion layer; wherein:
in a cross-sectional view of the semiconductor device taken transverse to the bit line, the magnetic layer and the upper adhesion layer together have a tapered shape and converge in a direction away from the bit line.

16. The semiconductor device according to claim 15, wherein:
the layer in contact with the bit line comprises an antidiffusion film.

17. The semiconductor device according to claim 16, further comprising:
a lower adhesion layer in contact with an upper surface of the antidiffusion film and also in contact with a lower surface of the magnetic layer; and wherein:
in a cross-sectional view of the semiconductor device taken transverse to the bit line, the lower adhesion layer, the magnetic layer and the upper adhesion layer together have a tapered shape and converge in a direction away from the bit line.

18. The semiconductor device according to claim 17, wherein a combined thickness of the lower adhesion layer, the magnetic layer and the upper adhesion layer is 10 nm or more and 50 nm or less.

19. The semiconductor device according to claim 16, wherein:
the antidiffusion film has a mixing layer containing a metal material for adhesion with the magnetic layer, the mixing layer extending from an upper surface of the antidiffusion film to a predetermined depth of the antidiffusion film; and
the upper surface of the antidiffusion film contacts a lower surface of the magnetic layer.

20. The semiconductor device according to claim 16, further comprising:
a lower adhesion layer in contact with an upper surface of the antidiffusion film and also in contact with a lower surface of the magnetic layer; and
a hard mask in contact with an upper surface of the upper adhesion layer; wherein:
in a cross-sectional view of the semiconductor device taken transverse to the bit line, the lower adhesion layer, the magnetic layer, the upper adhesion layer and the hard mask together have a tapered shape and converge in a direction away from the bit line.

21. The semiconductor device according to claim 20, wherein:
a sum of thicknesses of the upper adhesion layer and the hard mask is substantially identical to a thickness of the magnetic layer.

22. The semiconductor device according to claim 21, wherein:
the thickness of the magnetic layer is at 25 nm or more.

23. The semiconductor device according to claim 15, wherein:
the layer in contact with the bit line comprises a lower adhesion layer, without a separate antidiffusion layer present between the bit line and the lower adhesion layer;
the lower adhesion layer is also in contact with a lower surface of the magnetic layer; and
in a cross-sectional view of the semiconductor device taken transverse to the bit line, the lower adhesion layer, the magnetic layer and the upper adhesion layer together have a tapered shape and converge in a direction away from the bit line.

24. The semiconductor device according to claim 23, wherein a thickness of the lower adhesion layer is 1 nm or more.

25. The semiconductor device according to claim 24, wherein a combined thickness of the lower adhesion layer, the magnetic layer and the upper adhesion layer is 10 nm or more and 50 nm or less.

26. A method of manufacturing a yoke cover for a magnetic random access memory comprising a magnetoresistive element positioned between a digit line extending in a first direction below the magnetoresistive element and a bit line extending in a second direction above the magnetoresistive element, the method comprising:
forming a laminate film over the bit line by:
forming a lower adhesion layer over the bit line, the lower adhesion layer having an upper surface;
forming a magnetic layer in contact with the lower adhesion layer, the magnetic layer having an upper surface; and
forming an upper adhesion layer in contact with the upper surface of the magnetic layer, the upper adhesion layer having an upper surface;
forming a resist mask over the bit line;
patterning the upper adhesion layer by applying reactive ion etching with a halogen-based gas by using the resist mask as an etching mask;
applying reactive ion etching with ammonia and argon-based gas by using the patterned upper adhesion layer as an etching mask; and
applying reactive ion etching with a gas containing carbon as an element by using the patterned upper adhesion layer as an etching mask;
such that:
in a cross-sectional view of the semiconductor device taken transverse to the bit line, the lower adhesion layer, the magnetic layer and the upper adhesion layer together have a tapered shape and converge in a direction away from the bit line.
